(19) United States
(12) Patent Application Publication
(10) Pub. No.: US 2025/0233024 A1
(43) Pub. Date: Jul. 17, 2025

(54) METHOD OF MANUFACTURING ELECTRONIC DEVICE

(71) Applicant: InnoLux Corporation, Miao-Li County (TW)

(72) Inventors: Jia-Yuan CHEN, Miao-Li County (TW); Tsung-Han TSAI, Miao-Li County (TW); Kuan-Feng LEE, Miao-Li County (TW)

(73) Assignee: InnoLux Corporation, Miao-Li County (TW)

(21) Appl. No.: 18/977,962

(22) Filed: Dec. 12, 2024

(30) Foreign Application Priority Data
Jan. 16, 2024 (CN) 202410056687.4

(51) Int. Cl. H01L 21/66; H10H 20/01

(52) U.S. Cl. CPC H01L 22/12; H10H 20/019

(57) ABSTRACT

A method of manufacturing an electronic device includes: providing a first substrate with a plurality of electronic elements disposed thereon; inspecting at least part of the plurality of electronic elements on the first substrate to identify a first defective electronic element and a first normal electronic element; selectively transferring the first normal electronic element from the first substrate to a first location of a second substrate; and transferring a second normal electronic element to a second location of the second substrate corresponding to a location of the first defective electronic element on the first substrate.

### BACKGROUND OF THE DISCLOSURE

### 1. Field of the Disclosure

The present disclosure relates to a method of manufacturing an electronic device, and more particularly to a method of manufacturing an electronic device for improving a yield rate of the electronic device.

### 2. Description of the Prior Art

As the evolution and development of electronic devices, the electronic devices have become an indispensable item. For instance, a display device which is a kind of the electronic device has a displaying function, so as to transmit information and/or display an image.

In the manufacturing process of the electronic device, electronic elements would be disposed on a substrate by a transfer process, so as to enhance the manufacturing speed and the yield of the electronic device. However, with the trend of miniaturization of electronic elements, the yield rate of electronic elements disposed through the transfer process would be decreased as the size of the electronic elements is decreased, thereby decreasing the yield rate of the electronic device. Thus, the manufacturing method of the electronic device needs to be improved, so as to enhance the yield rate of the electronic device.

### SUMMARY OF THE DISCLOSURE

According to an embodiment, the present disclosure provides a method of manufacturing an electronic device. The method includes following steps: providing a first substrate with a plurality of electronic elements disposed thereon; inspecting at least part of the plurality of electronic elements on the first substrate to identify a first defective electronic element and a first normal electronic element; selectively transferring the first normal electronic element from the first substrate to a first location of a second substrate; and transferring a second normal electronic element to a second location of the second substrate corresponding to a location of the first defective electronic element on the first substrate.

### BRIEF DESCRIPTION OF THE DRAWINGS

FIG. 1 and FIG. 2 are schematic diagrams illustrating a flowchart of a method of manufacturing an electronic device according to an embodiment of the present disclosure.

FIG. 3 is a schematic diagram showing a cross-sectional view of a first inspecting process of a method of manufacturing an electronic device according to an embodiment of the present disclosure.

FIG. 4 is a schematic diagram showing a cross-sectional view of a first transfer process of a method of manufacturing an electronic device according to an embodiment of the present disclosure.

FIG. 5 is a schematic diagram showing a cross-sectional view of a mask, a first substrate, electronic elements and a second substrate of a method of manufacturing an electronic device according to an embodiment of the present disclosure.

FIG. 6 is a schematic diagram showing a top view of a mask, a first substrate and electronic elements of a method of manufacturing an electronic device according to another embodiment of the present disclosure.

FIG. 7 is a schematic diagram showing a cross-sectional view of a first transfer process performed by the mask, the first substrate and the electronic elements shown in FIG. 6.

FIG. 8 is a schematic diagram showing a cross-sectional view of a first transfer process of a method of manufacturing an electronic device according to an embodiment of the present disclosure.

FIG. 9 is a schematic diagram showing a cross-sectional view of a first transfer process of a method of manufacturing an electronic device according to another embodiment of the present disclosure.

FIG. 10 is a schematic diagram showing a cross-sectional view of a first transfer process of a method of manufacturing an electronic device according to still another embodiment of the present disclosure.

FIG. 11 is a schematic diagram showing a cross-sectional view of test processes of a laser beam in a method of manufacturing an electronic device according to an embodiment of the present disclosure.

FIG. 12 is a schematic diagram showing a top view of an alignment structure using in the first transfer process of a method of manufacturing an electronic device according to an embodiment of the present disclosure.

FIG. 13 is a schematic diagram showing a top view of a result of a first transfer process and a configuration of a first repairing process of a method of manufacturing an electronic device according to an embodiment of the present disclosure.

FIG. 14 is a schematic diagram showing a cross-sectional view of a second inspecting process and a second repairing process of a method of manufacturing an electronic device according to an embodiment of the present disclosure.

FIG. 15 is a schematic diagram showing a top view of the second inspecting process and the second repairing process of the method of manufacturing the electronic device according to the embodiment shown in FIG. 14.

FIG. 16 is a schematic diagram showing a top view of a second repairing process of a method of manufacturing an electronic device according to another embodiment of the present disclosure.

FIG. 17 is a schematic diagram showing a cross-sectional view of a second substrate and electronic elements of an electronic device according to an embodiment of the present disclosure.

FIG. 18 is a schematic diagram showing a cross-sectional view of a forming process of a filling layer of a method of manufacturing an electronic device according to an embodiment of the present disclosure.

FIG. 19 is a schematic diagram showing a cross-sectional view of a fourth inspecting process of a method of manufacturing an electronic device according to an embodiment of the present disclosure.

FIG. 20 is a schematic diagram showing a cross-sectional view of a fourth repairing process of a method of manufacturing an electronic device according to an embodiment of the present disclosure.

FIG. 21 is a schematic diagram showing a cross-sectional view of a fourth repairing process of a method of manufacturing an electronic device according to another embodiment of the present disclosure.

FIG. 22 is a schematic diagram showing a cross-sectional view of a fourth repairing process of a method of manufacturing an electronic device according to still another embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components with the same function but different names.

In the following description and in the claims, the terms “include”, “comprise” and “have” are used in an open-ended fashion, and thus should be interpreted to mean “include, but not limited to . . . ”. Thus, when the terms “include”, “comprise” and/or “have” are used in the description of the present disclosure, the corresponding features, regions, steps, operations and/or components would be pointed to existence, but not limited to the existence of one or a plurality of the corresponding features, regions, steps, operations and/or components.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each region, and/or each structure may be reduced or enlarged.

When the corresponding component such as layer or region is referred to “on another component”, it may be directly on this another component, or other component (s) may exist between them. On the other hand, when the component is referred to “directly on another component (or the variant thereof)”, any component does not exist between them. Furthermore, when the corresponding component is referred to “on another component”, the corresponding component and the another component have a disposition relationship along a top-view/vertical direction, the corresponding component may be below or above the another component, and the disposition relationship along the top-view/vertical direction are determined by an orientation of the device.

It will be understood that when a component or layer is referred to as being “connected to” another component or layer, it can be directly connected to this another component or layer, or intervening components or layers may be presented. In contrast, when a component is referred to as being “directly connected to” another component or layer, there are no intervening components or layers presented. In addition, when the component is referred to “be coupled to/with another component (or the variant thereof)”, it may be directly connected to this another component, or may be indirectly connected (such as electrically connected) to this another component through other component(s).

In the present disclosure, when a component is “electrically connected to” another component, an electrical signal would flow between these two components at certain times during normal operation. In the present disclosure, when a component is “couple to” another component, an electrical signal would flow between these two components within a designated time. In the present disclosure, when a component is “disconnected from” another component, an electrical signal would not flow between these two components within a designated time.

In the description and following claims, the term “horizontal direction” generally means a direction parallel to a horizontal plane, the term “horizontal plane” generally means a surface parallel to a direction X and direction Y in the drawings, the term “vertical direction” generally means a direction parallel to a direction Z and perpendicular to the horizontal direction in the drawings, and the direction X, the direction Y and the direction Z are perpendicular to each other. In the description and following claims, the term “top view” generally means a viewing result viewing along the vertical direction. In the description and following claims, the term “cross-sectional view” generally means a structure cut along the vertical direction is viewed along the horizontal direction.

In the description and following claims, it should be noted that the term “overlap” means that two elements overlap along the direction Z, and the term “overlap” can be “partially overlap” or “completely overlap” in unspecified circumstances.

The terms “about”, “approximately”, “substantially”, “equal”, or “same” generally mean within ±20% of a given value or range, or mean within ±10%, ±5%, ±3%, ±2%, ±1%, or ±0.5% of a given value or range.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It should be noted that the technical features in different embodiments described in the following can be replaced, recombined, or mixed with one another to constitute another embodiment without departing from the spirit of the present disclosure.

In the present disclosure, the electronic device may include a display device, a lighting device, an antenna device, a sensing device, a tiled device or a combination thereof, but not limited thereto. The display device may be a non-self-luminous type display device or a self-luminous type display device based on requirement(s), and the display device may be a color display device or a monochrome display device based on requirement(s). The antenna device may be a liquid-crystal-type antenna device or a non-liquid-crystal-type antenna device, the sensing device may be a device for sensing capacitance, light, thermal or ultrasonic, and the tiled device may be a tiled display device or a tiled antenna device, but not limited thereto. Electronic components in the electronic device may include passive component(s) and active component(s), such as capacitor(s), resistor(s), inductor(s), diode(s), transistor(s) and/or integrated circuit(s), but not limited thereto. The diode may include a light emitting diode (LED) or a photodiode. The light emitting diode may include an organic light emitting diode (OLED), a mini LED, a micro LED or a quantum dot LED, but not limited thereto. The transistor may include a top gate thin film transistor, a bottom gate thin film transistor or a dual gate thin film transistor, but not limited thereto. The electronic device may include fluorescence material, phosphorescence material, quantum dot (QD) material or other suitable material based on requirement(s), but not limited thereto. The electronic device may have a peripheral system (such as a driving system, a control system, a light system, etc.) for supporting the device(s) and the component(s) in the electronic device.

For example, in the following, the electronic device has a displaying function for displaying an image.

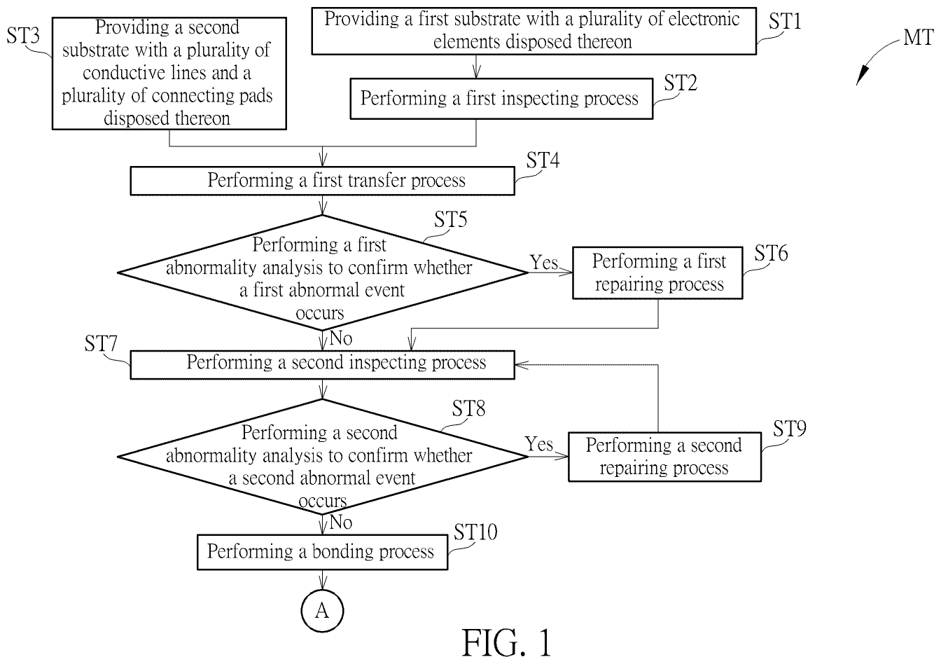

Referring to FIG. 1 and FIG. 2, FIG. 1 and FIG. 2 are schematic diagrams illustrating a flowchart of a method of manufacturing an electronic device according to an embodiment of the present disclosure. Note that the manufacturing method MT of the present disclosure is not limited by the following embodiments and figures. In some embodiments, any other suitable step may be added before or after one of the existing steps of the manufacturing method MT, and/or some steps may be performed simultaneously or separately. In some embodiments, the process sequence of the manufacturing method MT may be adjusted based on requirement(s).

In the manufacturing method MT, a forming process of a layer and/or a structure may include an atomic layer deposition (ALD), a chemical vapor deposition (CVD), a physical vapor deposition (PVD), a coating process, any other suitable process or a combination thereof. In the manufacturing method MT, a patterning process may include a photolithography, an etching process, any other suitable process or a combination thereof, wherein the etching process may be a wet etching process, a dry etching process, any other suitable etching process, or a combination thereof.

In the following manufacturing method MT, an inspecting process can inspect a target element through any suitable manner, so as to identify whether the target element is a normal element or a defective element. The target element is identified as a normal element when it meets all inspecting specifications, and the target element is identified as a defective element when it does not meet at least one of the inspecting specifications. In the present disclosure, the normal element is an electronic unit that can operate normally, and the defective element is an electronic unit that cannot operate normally. For instance, if the electronic unit is a light emitting element, the normal light emitting element can emit light according to a given gray level, and the defective light emitting element cannot emit light according to a given gray level (i.e., the defective light emitting element can be flicker and/or be a dark spot, a constant bright spot). In the following manufacturing method MT, a repairing process can process the defective element in any suitable manner, so as to convert/replace the defective element with the normal element, remove the defective element, and/or disable the defective element.

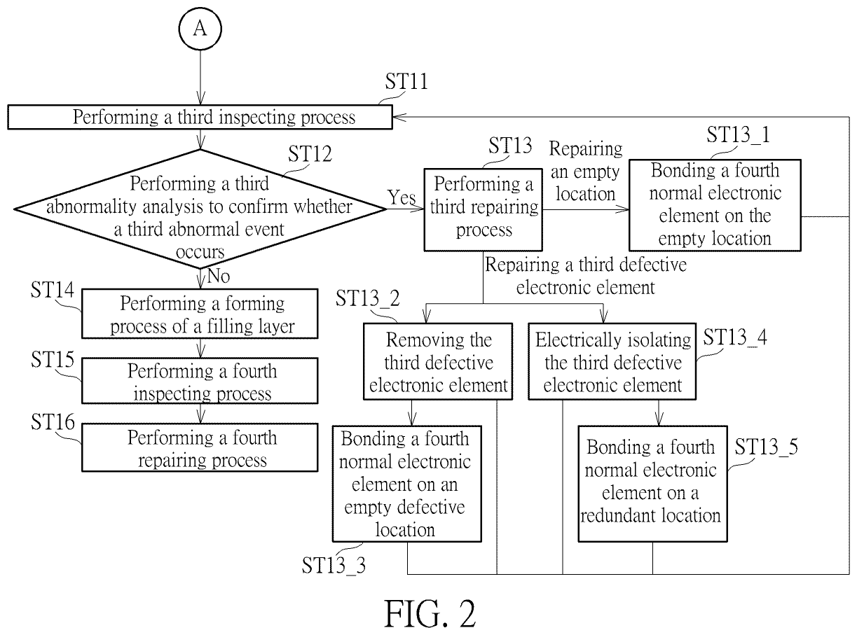

Referring to FIG. 3 with FIG. 1, FIG. 3 is a schematic diagram showing a cross-sectional view of a first inspecting process of a method of manufacturing an electronic device according to an embodiment of the present disclosure. As shown in FIG. 1 and FIG. 3, in a step ST1 of the manufacturing method MT of the electronic device, the first substrate 110 with a plurality of electronic elements EC disposed thereon is provided. The first substrate 110 may be rigid or flexible, and the first substrate 110 may include suitable material based on its type. For instance, the first substrate 110 may include glass, quartz, ceramic, sapphire, polymer (e.g., polyimide (PI), polyethylene terephthalate (PET), etc.), other suitable materials or a combination thereof. Note that a normal direction of the first substrate 110 may be parallel to the direction Z.

The electronic element EC may be any suitable element, and the electronic element EC may be transferred by a transfer process. In some embodiments, the electronic element EC may be a light emitting element for displaying an image, or the electronic element EC may be an element configured to perform sensing (i.e., light sensing or other suitable sensing) or to assist in sensing. For instance, the electronic element EC may be a diode (e.g., LED or photodiode), but not limited thereto. In an embodiment that the electronic element EC is a light emitting element (e.g., LED), as shown in FIG. 3, the electronic element EC may include an electrode E1, an electrode E2, a first semiconductor layer SM1, a second semiconductor layer SM2 and a light emitting layer AL. The electrode E1 may be electrically connected to the first semiconductor layer SM1 (the electrode E1 may be directly in contact with the first semiconductor layer SM1), the electrode E2 may be electrically connected to the second semiconductor layer SM2 (the electrode E2 may be directly in contact with the second semiconductor layer SM2), and the light emitting layer AL may be disposed between the first semiconductor layer SM1 and the second semiconductor layer SM2. For example, the first semiconductor layer SM1 may be a P-type semiconductor layer, the second semiconductor layer SM2 may be an N-type semiconductor layer, and the light emitting layer AL may be a multiple quantum well (MQW), but not limited thereto. In FIG. 3, the electrode E1 and the electrode E2 may be disposed on the same side in the electronic element EC (i.e., the electrode E1 and the electrode E2 may be disposed on the same side of the second semiconductor layer SM2), or the electrode E1 and the electrode E2 may be disposed at suitable positions based on requirement(s). In FIG. 3, the second semiconductor layer SM2 may be between the first substrate 110 and the electrode E1 (the electrode E2). In FIG. 3, the electronic element EC may be disposed on the first substrate 110 through a first adhesive layer 120, but not limited thereto.

As shown in FIG. 1 and FIG. 3, in a step ST2 of the manufacturing method MT of the electronic device, the first inspecting process DP1 is performed. In the first inspecting process DP1, at least part of the electronic elements EC on the first substrate 110 may be inspected by the detector DTT1, so as to identify a first defective electronic element ECd1 and a first normal electronic element ECn1 and to generate a first inspecting result (e.g., a chart), wherein the first inspecting process DP1 may inspect the electronic element EC on the first substrate 110 through any suitable manner. For instance, FIG. 3 shows two first normal electronic elements ECn1 and one first defective electronic element ECd1. In some embodiments, the first inspecting process DP1 may include a visual inspection, a lighting inspection, an electrical inspection, other suitable inspection or a combination thereof, and the detector DTT1 may be correspondingly adjusted according to the inspection(s) of the first inspecting process DP1.

In the visual inspection, the appearance of the electronic element EC may be inspected through an appropriate instrument, so as to confirm whether the electronic element EC is damaged and/or has other defects. For instance, the visual inspection may be performed through automated optical inspection (AOI), but not limited thereto.

In the lighting inspection, the electronic element EC may be illuminated to get the energy, such that the luminous effect of the electronic element EC (e.g., LED) may be inspected (e.g., the lighting inspection confirms whether the luminous color of the electronic element EC meets the requirement(s) and/or whether the electronic element EC emits light).

In the electrical inspection, an appropriate instrument may be used to provide electrical signal(s) to the electronic element EC to conduct an electrical test on the electronic element EC, thereby confirming whether the electronic element EC operates according to the electrical signal (s). In some embodiments, the electronic element EC may receive the electrical signal(s) through the probes directly in contact with the electrode E1 and the electrode E2 of the electronic element EC.

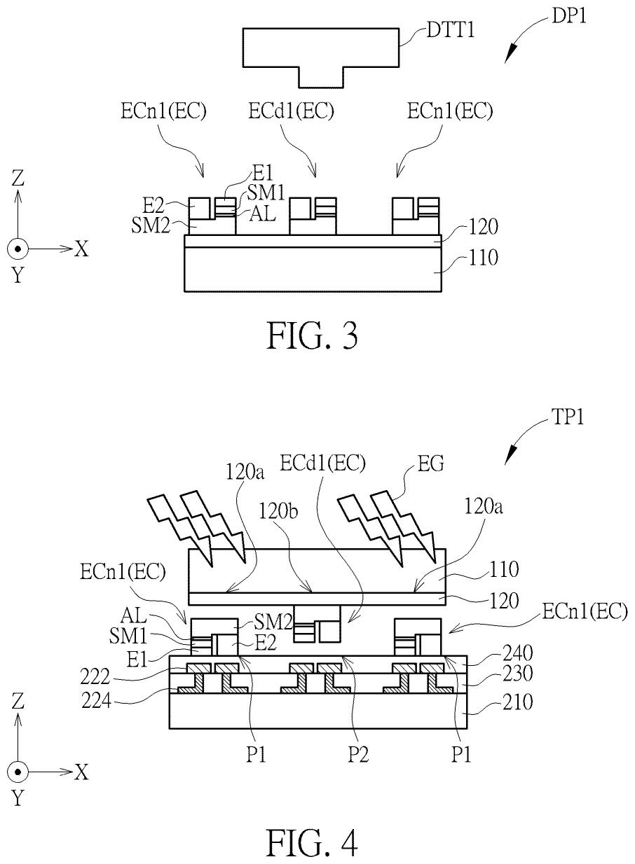

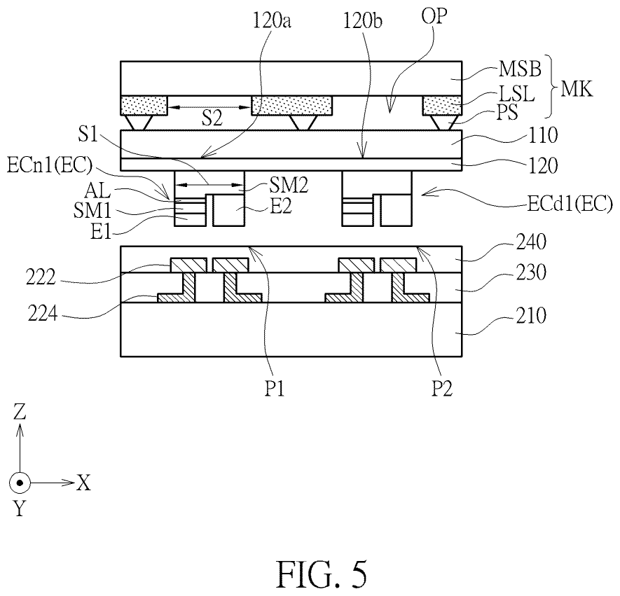

Referring to FIG. 4 and FIG. 5 with FIG. 1, FIG. 4 is a schematic diagram showing a cross-sectional view of a first transfer process of a method of manufacturing an electronic device according to an embodiment of the present disclosure, and FIG. 5 is a schematic diagram showing a cross-sectional view of a mask, a first substrate, electronic elements and a second substrate of a method of manufacturing an electronic device according to an embodiment of the present disclosure. As shown in FIG. 1 and FIG. 4, in a step ST3 of the manufacturing method MT of the electronic device, a second substrate 210 with a plurality of conductive lines 224 and a plurality of connecting pads 222 disposed thereon is provided. The second substrate 210 may be rigid or flexible, and the second substrate 210 may include suitable material based on its type. For instance, the second substrate 210 may include glass, quartz, ceramic, sapphire, polymer (e.g., PI, PET, etc.), other suitable materials or a combination thereof. A normal direction of the second substrate 210 may be parallel to the direction Z, and the size of the first substrate 110 may be greater than, less than or the same as the size of the second substrate 210.

In the present disclosure, at least one conductive layer and at least one insulating layer may be disposed on the second substrate 210, and the conductive line 224 and the connecting pad 222 may be conductive structures belonging to the conductive layer. For instance, the material of the conductive layer may include metal, transparent conductive material (such as indium tin oxide (ITO), indium zinc oxide (IZO), etc.), other suitable conductive material (s) or a combination thereof, and the material of the insulating layer may include silicon oxide (SiOₓ), silicon nitride (SiN_{y}), silicon oxynitride (SiOₓN_{y}), organic insulating material (e.g., photosensitive resin), other suitable insulating material(s) or a combination thereof. In FIG. 4, the insulating layer 230 disposed on the second substrate 210 may separate the conductive line 224 from at least a part of the connecting pad 222. In some embodiments, the conductive lines 224 may include a plurality of data lines and a plurality of scan lines, wherein the data line may be configured to transmit a data signal related to the displaying image, and the scan line may be configured to transmit a switching signal controlling a switching component. For example, the data lines may (substantially) extend along the direction Y and be arranged in the direction X, and the scan lines may (substantially) extend along the direction X and be arranged in the direction Y, but not limited thereto.

As shown in FIG. 1 and FIG. 4, in a step ST4 of the manufacturing method MT of the electronic device, a first transfer process TP1 is performed to selectively transfer the first normal electronic element (s) ECn1 from the first substrate 110 to the second substrate 210, and the first transfer process TP1 does not transfer the first defective electronic element ECd1 from the first substrate 110 to the second substrate 210. In the first transfer process TP1 of the present disclosure, the content “selectively transferring the first normal electronic element(s) ECn1 from the first substrate 110 to the second substrate 210” means that the first normal electronic element(s) ECn1 would be transferred only and the first defective electronic element(s) ECd1 would not be transferred, and also, all first normal electronic elements ECn1 or some first normal electronic elements ECn1 would be transferred according to requirement(s).

As shown in FIG. 4, in the first transfer process TP1, an alignment process is performed to make the first substrate 110 be aligned with the second substrate 210 in the direction Z, such that the first normal electronic element ECn1 on the first substrate 110 is corresponding to and overlaps a first location P1 of the second substrate 210 in the direction Z, and the first defective electronic element ECd1 on the first substrate 110 is corresponding to and overlaps a second location P2 of the second substrate 210 in the direction Z. Then, the first normal electronic element ECn1 is separated from the first substrate 110 by any suitable manner, so as to selectively transfer the first normal electronic element ECn1 from the first substrate 110 to the first location P1 of the second substrate 210 and to leave the first defective electronic element ECd1 on the first substrate 110, thereby completing the first transfer process TP1. The first normal electronic element ECn1 is adhered to the second substrate 210 through the second adhesive layer 240 disposed on the second substrate 210, so as to make the first normal electronic element ECn1 temporarily fixed on the second substrate 210. In some embodiments (as shown in FIG. 4), a number of the first normal electronic elements ECn1 transferred by the first transfer process TP1 may be greater than 1 (i.e., in the first transfer process TP1, a number of the first normal electronic elements ECn1 separated from the first substrate 110 may be greater than 1). For instance, the first transfer process TP1 may be a mass transfer process, but not limited thereto.

In some embodiments, the first transfer process TP1 is to provide sufficient energy EG to the first adhesive layer 120 between the first normal electronic element ECn1 and the first substrate 110 to reduce the adhesive effect of the first adhesive layer 120, thereby separating the first normal electronic element ECn1 from the first substrate 110. In FIG. 4, a portion of the first adhesive layer 120 directly in contact with the first normal electronic element ECn1 is referred as a first portion 120a, a portion of the first adhesive layer 120 directly in contact with the first defective electronic element ECd1 is referred as a second portion 120b, the first transfer process TP1 is to provide sufficient energy EG to the first portion 120a of the first adhesive layer 120 to separate the first normal electronic element ECn1 from the first substrate 110, and the first transfer process TP1 is not to provide sufficient energy EG to the second portion 120b of the first adhesive layer 120 to make the first defective electronic element ECd1 constantly adhered to the first substrate 110 through the first adhesive layer 120.

For instance, the first transfer process TP1 may be a laser transfer process, such that the step of selectively transferring the first normal electronic element ECn1 may be performed through the laser transfer process, and a laser beam may serve as the energy EG configured to separate the first normal electronic element ECn1 from the first substrate 110. In the laser transfer process, the first normal electronic element ECn1 may be separated from the first substrate 110 by making the laser beam irradiates a desired position of the first substrate 110 (i.e., a position corresponding to the first normal electronic element ECn1) and/or the first portion 120a of the first adhesive layer 120. In the laser transfer process, the laser beam does not irradiate the second portion 120b of the first adhesive layer 120 (or a position of the first substrate 110 corresponding to the first defective electronic element ECd1), such that the first defective electronic element ECd1 is constantly adhered to the first substrate 110 through the first adhesive layer 120. For example, the laser beam irradiates along the direction Z, but not limited thereto. In the laser transfer process, the laser beam may irradiate the first portion 120a of the first adhesive layer 120 to make the first portion 120a sinter, thereby reducing the adhesive force of the first portion 120a of the first adhesive layer 120.

As shown in FIG. 4 and FIG. 5, the first transfer process TP1 may further provide a mask MK to enhance the transferring effect of the first transfer process TP1 (e.g., the laser transfer process) and/or make the required electronic element (s) EC separated from the first substrate 110, wherein the mask MK may be disposed on the first substrate 110 in the direction Z and aligned with the first substrate 110 in the direction Z according to the required position. Therefore, after performing the alignment process in the first transfer process TP1, the first substrate 110 may be between the mask MK and the second substrate 210. In FIG. 5, the mask MK may include a light shielding layer LSL having at least one opening OP, and the light may be shielded by the light shielding layer LSL and pass through the opening OP, wherein the light shielding layer LSL may include any suitable material. For instance, the light shielding layer LSL may include metal, photoresist, ink, resin, pigment, other suitable material or a combination thereof, but not limited thereto. In FIG. 5, each opening OP of the light shielding layer LSL may be corresponding to one electronic element EC in the direction Z, and the light shielding layer LSL may overlap the electronic element EC that does not need to be transferred and an interval between two adjacent electronic elements EC in the direction Z.

In some embodiments, the light shielding layer LSL and the opening(s) OP in the mask MK are designed based on the transferring position(s) of the electronic element(s) EC on the second substrate 210, and thus, the designs of the light shielding layer LSL and the opening(s) OP may not be related to the first inspecting result of the first inspecting process DP1. Namely, the designs of the light shielding layer LSL and the opening(s) OP may not be related to the distribution of the first defective electronic element(s) ECd1 and the first normal electronic element(s) ECn1 on the first substrate 110, such that each opening OP may be corresponding to the first normal electronic element ECn1 or the first defective electronic element ECd1. In some embodiments, a transfer region may be determined on the second substrate 210, and then, the light shielding layer LSL and the opening(s) OP in the mask MK may be designed based on the transfer region of the second substrate 210, wherein a minimum region of the mask MK containing all openings OP may be defined as a preset region (i.e., the preset region of the mask MK is determined by the transfer region of the second substrate 210, and all openings OP are situated in the preset region).

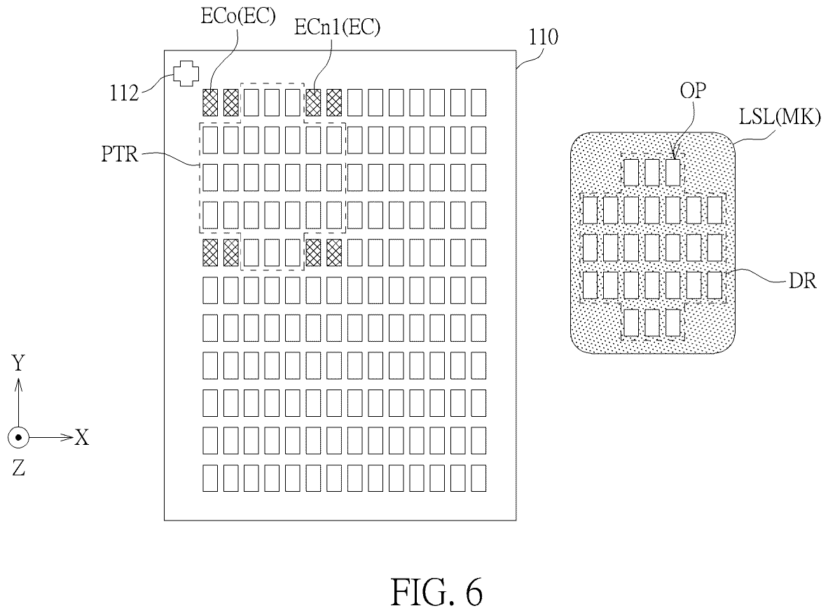

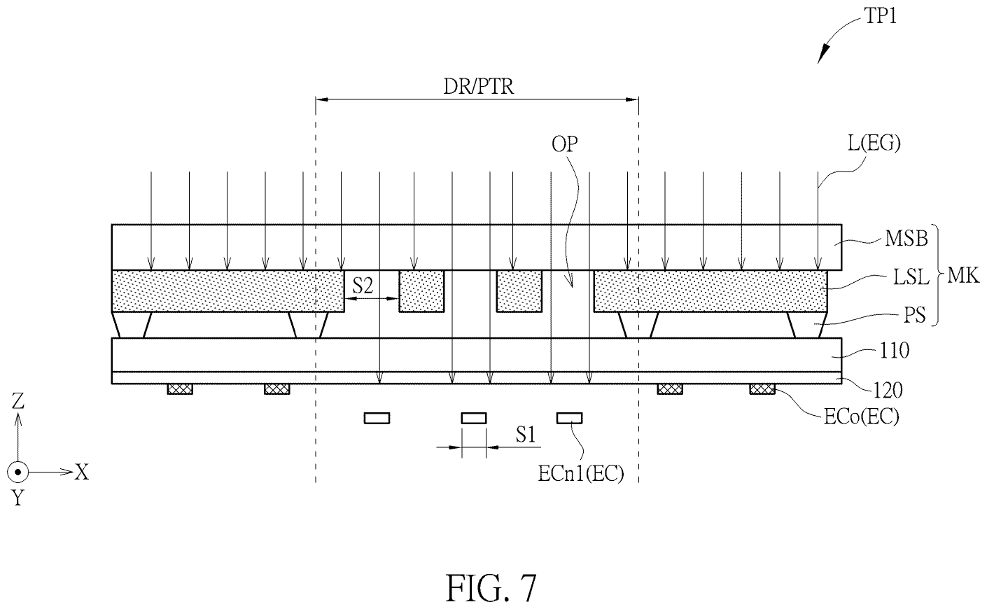

For instance, both the first substrate 110 and the second substrate 210 may be rectangular, and therefore, the transfer region of the second substrate 210 may be rectangular, such that the preset region of the mask MK may be rectangular, but not limited thereto. For instance (as shown in FIG. 6 and FIG. 7), when the shape of the second substrate 210 is different from the shape of the first substrate 110 or the second substrate 210 is ultimately made into a shape different from the shape of the first substrate 110 (e.g., the first substrate 110 is rectangular, the second substrate 210 is circular), the preset region DR of the mask MK may be corresponding to the transfer region of the second substrate 210 (i.e., the preset region DR may be corresponding to the circular transfer region).

Moreover, in the mask MK and the first substrate 110 shown in FIG. 6 and FIG. 7, some electronic elements EC may not situated in the preset region DR due to the design of the preset region DR, and the first transfer process TP1 may not transfer the electronic elements EC situated outside the preset region DR even if these electronic elements EC are normal. Accordingly, in the embodiment shown in FIG. 6 and FIG. 7, the first normal electronic element ECn1 is situated in the preset region DR of the mask MK (i.e., the first normal electronic element ECn1 is situated in a predetermined transfer region PTR of the first substrate 110 shown in FIG. 6), other normal electronic elements ECo are situated outside the preset region DR of the mask MK (i.e., other normal electronic element ECo are situated outside the predetermined transfer region PTR of the first substrate 110 shown in FIG. 6). Since the light shielding layer LSL in the preset region DR has the opening(s) OP and the light shielding layer LSL outside the preset region DR does not have the opening OP, when the mask MK is disposed on the first substrate 110, the first normal electronic element ECn1 is corresponding to and overlaps the opening OP in the preset region DR of the mask MK in the direction Z (i.e., the mask MK has a transmissive region situated in the preset region DR and corresponding to the first normal electronic element ECn1), and other normal electronic element ECo is corresponding to the light shielding layer LSL outside the preset region DR (i.e., the mask MK has a non-transmissive region situated outside the preset region DR and corresponding to other normal electronic element ECo), such that the first transfer process TP1 may transfer the first normal electronic element ECn1 from the first substrate 110 to the second substrate 210 and not transfer other normal electronic element ECo from the first substrate 110 to the second substrate 210.

Note that the size of the mask MK may be related to the size of the first substrate 110. For instance, the size of the mask MK may be the same as the size of the first substrate 110, but not limited thereto.

In FIG. 5 and FIG. 7, in order to enhance the transferring effect of the first transfer process TP1 (e.g., the laser transfer process) and/or to make the required electronic element(s) EC separated from the first substrate 110, a size S2 of the opening OP of the light shielding layer LSL in the horizontal direction (e.g., the direction X or the direction Y) is greater than a size S1 of the electronic element EC in the horizontal direction (e.g., the direction X or the direction Y). For instance, in FIG. 5 and FIG. 7, a ratio of the size S2 of the opening OP of the light shielding layer LSL in the horizontal direction (e.g., the direction X) to the size S1 of the electronic element EC in this horizontal direction (e.g., the direction X) may be greater than 1.1, but not limited thereto.

In the first transfer process TP1 (e.g., the laser transfer process), in order to make the first portion 120a of the first adhesive layer 120 obtain sufficient energy EG and to prevent the second portion 120b of the first adhesive layer 120 from obtaining sufficient energy EG, any suitable manner can be used to reduce the energy EG obtained by the second portion 120b of the first adhesive layer 120 or to prevent the second portion 120b of the first adhesive layer 120 from obtaining the energy EG. In some embodiments, through the combination of the light shielding layer LSL and other structure (s), the first portion 120a of the first adhesive layer 120 may obtain sufficient energy EG, and the second portion 120b of the first adhesive layer 120 may not obtain sufficient energy EG.

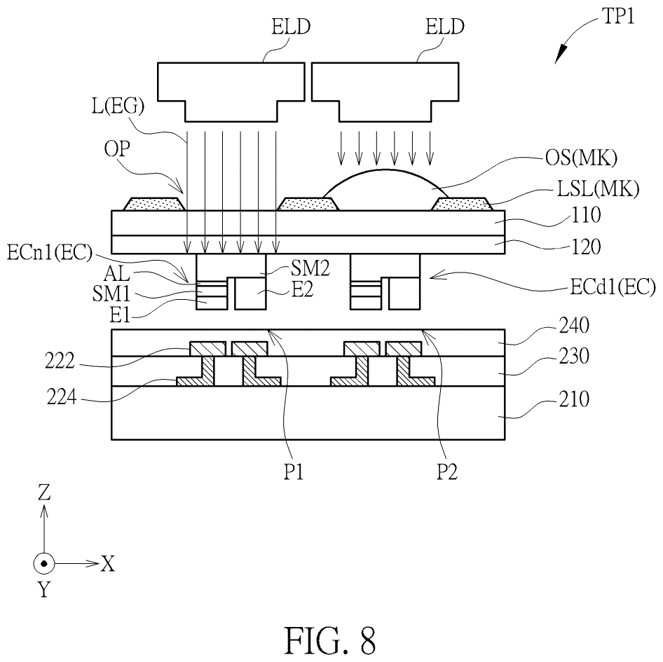

For instance, as shown in FIG. 8, in an embodiment, the mask MK may include a light-shielding structure OS disposed in the opening OP of the light shielding layer LSL and having a width greater than or equal to a width of the opening OP, wherein the light-shielding structure OS may be corresponding to the first defective electronic element ECd1 and the second portion 120b of the first adhesive layer 120 in the direction Z, so as to reduce the energy EG obtained by the second portion 120b of the first adhesive layer 120 or to prevent the second portion 120b of the first adhesive layer 120 from obtaining the energy EG in the first transfer process TP1. Accordingly, the mask MK of this embodiment may have the transmissive region corresponding to the first normal electronic element ECn1 (i.e., the light shielding layer LSL and the light-shielding structure OS may not disposed in the transmissive region) and the non-transmissive region corresponding to the first defective electronic element ECd1 (i.e., the light shielding layer LSL and/or the light-shielding structure OS may be disposed in the non-transmissive region). In the condition that the first transfer process TP1 is the laser transfer process, the laser beam L emitted from an emitter ELD may pass through the transmissive region to irradiate the first substrate 110 and the first portion 120a of the first adhesive layer 120, thereby making the first normal electronic element ECn1 separated from the first substrate 110. In the condition that the first transfer process TP1 is the laser transfer process, the light-shielding structure OS disposed in the non-transmissive region may reduce or avoid the penetration of the laser beam L, such that the second portion 120b of the first adhesive layer 120 may not obtain sufficient energy EG, thereby making the first defective electronic element ECd1 constantly adhered to the first substrate 110 through the first adhesive layer 120. Furthermore, the light-shielding structure OS may include an opaque material. For example, the light-shielding structure OS may include metal, photoresist, ink, resin, pigment, other suitable material or a combination thereof.

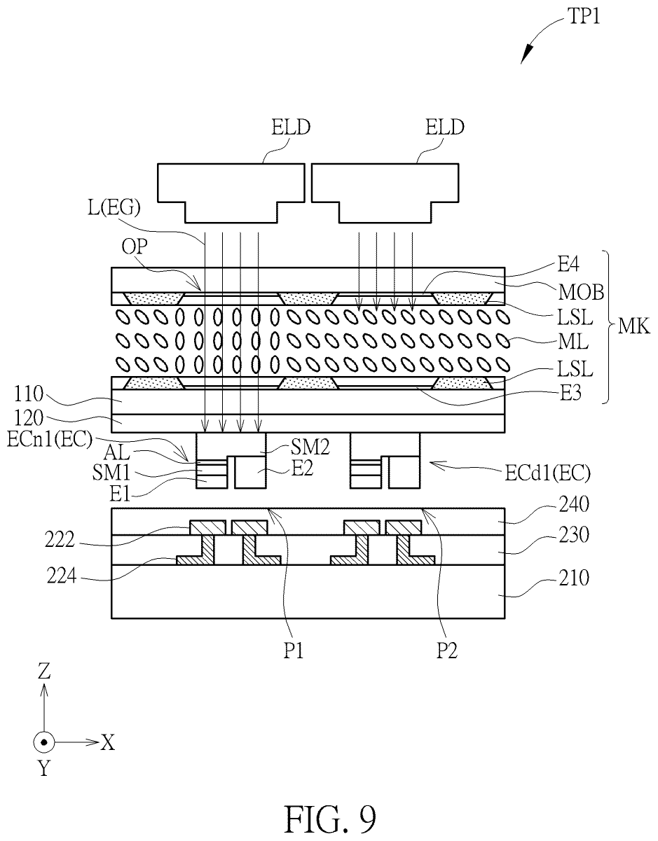

For example, as shown in FIG. 9, in another embodiment, the mask MK may be an electronically controlled mask including the light shielding layer LSL. Therefore, the light transmittance of a region of the mask MK corresponding to the opening OP may be controlled by the electrical signal (s). In FIG. 9, the mask MK may include an electrical control medium layer ML, a controlling electrode E3 and a controlling electrode E4 (the controlling electrode E3 and the controlling electrode E4 may be disposed on the same side or different sides of the electrical control medium layer ML), wherein the controlling electrode E3 and the controlling electrode E4 may receive required electrical signals to generate a corresponding electric field. The state of the electrical control medium layer ML may be controlled through the electric field caused by the controlling electrode E3 and the controlling electrode E4. Thus, in the first transfer process TP1, the light transmittance of a region of the mask MK corresponding to the opening OP may be controlled by the electrical signals, such that the first portion 120a of the first adhesive layer 120 may obtain sufficient energy EG and the second portion 120b of the first adhesive layer 120 may not obtain sufficient energy EG. Accordingly, the mask MK of this embodiment may be controlled by the electrical signals to make the transmissive region corresponding to the first normal electronic element ECn1 and to make the non-transmissive region corresponding to the first defective electronic element ECd1. In the condition that the first transfer process TP1 is the laser transfer process, the laser beam L emitted from the emitter ELD may pass through the transmissive region to irradiate the first substrate 110 and the first portion 120a of the first adhesive layer 120, thereby making the first normal electronic element ECn1 separated from the first substrate 110. In the condition that the first transfer process TP1 is the laser transfer process, the non-transmissive region of the mask MK may reduce or avoid the penetration of the laser beam L, such that the second portion 120b of the first adhesive layer 120 may not obtain sufficient energy EG, thereby making the first defective electronic element ECd1 constantly adhered to the first substrate 110 through the first adhesive layer 120. Furthermore, for example, the controlling electrode E3 and the controlling electrode E4 may include a transparent conductive layer, the electrical control medium layer ML may include liquid crystal molecules, and the liquid crystal molecules may rotate through the electric field caused by the controlling electrode E3 and the controlling electrode E4, but not limited thereto.

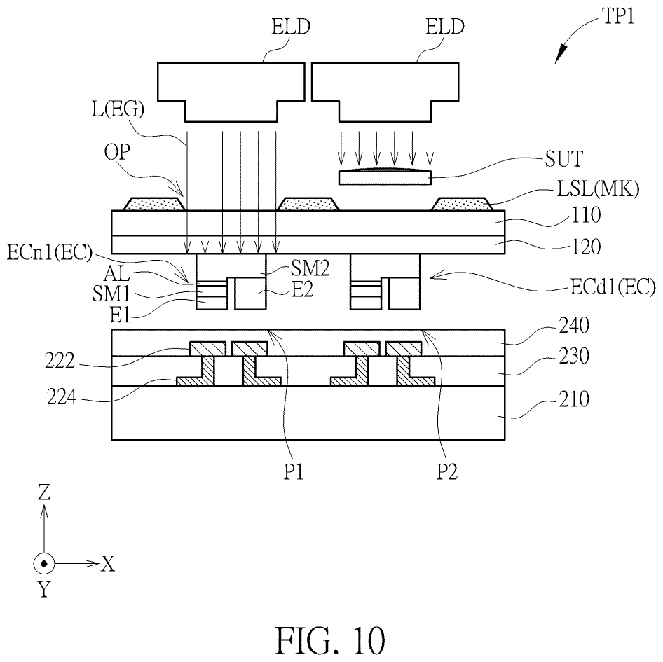

For example, as shown in FIG. 10, in still another embodiment, a light-shielding component SUT may be further provided in addition to the mask MK, wherein the light-shielding component SUT may overlap the first defective electronic element ECd1 and the second portion 120b of the first adhesive layer 120 in the direction Z, so as to reduce the energy EG obtained by the second portion 120b of the first adhesive layer 120 or to prevent the second portion 120b of the first adhesive layer 120 from obtaining the energy EG in the first transfer process TP1. In the condition that the first transfer process TP1 is the laser transfer process, the laser beam L emitted from the emitter ELD may pass through the opening OP corresponding to the first normal electronic element ECn1 to irradiate the first substrate 110 and the first portion 120a of the first adhesive layer 120, thereby making the first normal electronic element ECn1 separated from the first substrate 110. In the condition that the first transfer process TP1 is the laser transfer process, the light-shielding component SUT may reduce or avoid the penetration of the laser beam L, such that the second portion 120b of the first adhesive layer 120 may not obtain sufficient energy EG, thereby making the first defective electronic element ECd1 constantly adhered to the first substrate 110 through the first adhesive layer 120. For instance, the mask MK may be disposed between the light-shielding component SUT and the first substrate 110, but not limited thereto. For instance, the light-shielding component SUT may be a shutter, wherein the shutter may be closed when the shutter overlaps the first defective electronic element ECd1 and the second portion 120b of the first adhesive layer 120.

In the present disclosure, the relation between the mask MK and the first substrate 110 may be designed based on requirement (s). In the embodiment shown in FIG. 5, the mask MK and the first substrate 110 may be two separated structures, wherein the mask MK may further include a mask substrate MSB, and the light shielding layer LSL may be disposed on the mask substrate MSB. In the first transfer process TP1, the mask MK and the first substrate 110 which are separated from each other may be aligned with each other, such that the mask MK may overlap the first substrate 110 in the direction Z, and the opening OP of the light shielding layer LSL of the mask MK may be corresponding to the electronic element EC in the direction Z. Furthermore, in the embodiment shown in FIG. 5, the mask MK may further include a protruding structure PS disposed on the mask substrate MSB, wherein the protruding structure PS may be between the mask substrate MSB and the first substrate 110 in the first transfer process TP1, so as to reduce the separating difficulty and the moving difficulty of the mask MK and the first substrate 110, thereby reducing the damage producing on the mask MK and the first substrate 110 during the first transfer process TP1. For example, the light shielding layer LSL may be disposed between the protruding structure PS and the mask substrate MSB, but not limited thereto.

In the embodiments shown in FIG. 8 to FIG. 10, the mask MK and the first substrate 110 may be integrated into one structure, wherein the light shielding layer LSL of the mask MK may be formed on the first substrate 110. For instance, the first substrate 110 may be between the light shielding layer LSL and the electronic element EC, but not limited thereto. Furthermore, in FIG. 9, the mask MK may further include a mask opposite substrate MOB, such that the electrical control medium layer ML may be disposed between the mask opposite substrate MOB and the first substrate 110. In these designs, the alignment accuracy between the mask MK and the first substrate 110 may be increased, and the alignment step for making the mask MK aligned with the first substrate 110 may be omitted.

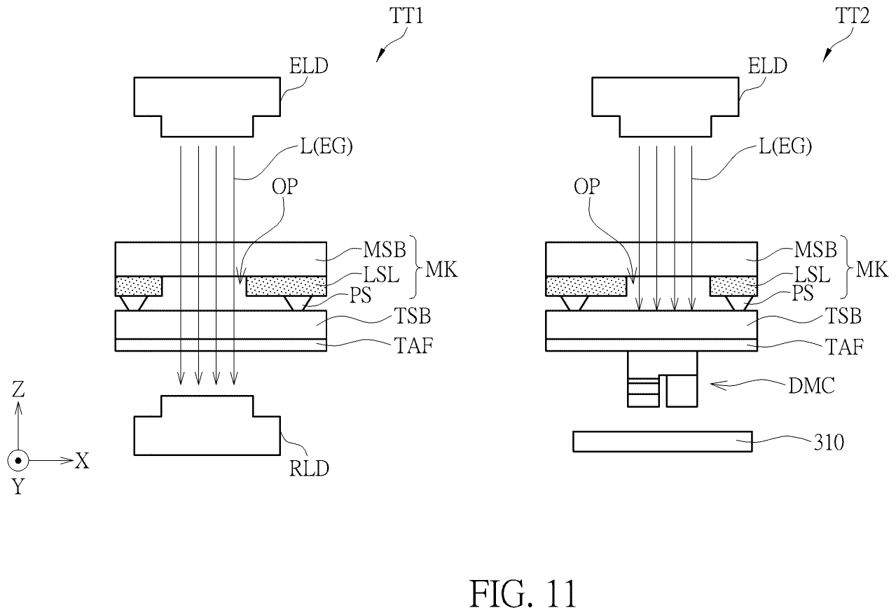

Moreover, in the manufacturing method MT of the electronic device, before the laser transfer process serving as the first transfer process TP1 is performed, a testing process of the laser beam L may be optionally performed, so as to appropriately calibrate the laser transfer process, thereby improving the successful rate of the manufacturing method MT of the electronic device. Referring to FIG. 11, FIG. 11 is a schematic diagram showing a cross-sectional view of test processes of a laser beam in a method of manufacturing an electronic device according to an embodiment of the present disclosure, wherein these test processes are configured to improve the sintering effect on the adhesive layer (e.g., the first adhesive layer 120) caused by of the laser beam L. Note that the sintering energy required for sintering is the product of the energy density of the laser beam L (the unit of the energy density is joule/square centimeter (J/cm²)) and the irradiating time of the laser beam L (the unit of the irradiating time is nanoseconds (ns)). Therefore, in the condition of the same required sintering energy, the energy density of the laser beam L is inversely proportional to the irradiating time of the laser beam L.

In a first test TT1 of the laser beam L shown in FIG. 11, a receiver RLD configured to receive the laser beam L and a test substrate TSB are provided, wherein the structure of the test substrate TSB may be the same as or similar to the structure of the first substrate 110, a test adhesive layer TAF disposed on the test substrate TSB may be the same as or similar to the first adhesive layer 120, and the mask MK and the test substrate TSB may be between the emitter ELD and the receiver RLD. The laser beam L emitted from the emitter ELD may pass through the mask MK, the test substrate TSB and the test adhesive layer TAF in sequence and finally enter the receiver RLD, and the receiver RLD may be configured to sense the energy density of the received laser beam L. Therefore, the energy density of the laser beam L and/or the irradiating time of the laser beam L may be adjusted according to the sensing result of the receiver RLD, so as to improve the sintering effect, thereby improving the successful rate of the manufacturing process.

In a second test TT2 of the laser beam L shown in FIG. 11, the test substrate TSB may be provided, and a plurality of dummy elements DMC may be disposed on the test substrate TSB through the test adhesive layer TAF. Then, a preset laser transfer process is performed to transfer the dummy element DMC from the test substrate TSB to a third substrate 310 different from the first substrate 110 and the second substrate 210. In the second test TT2, the energy density of the laser beam L and/or the irradiating time of the laser beam L may be adjusted according to a desorption rate of the dummy elements DMC (i.e., a ratio of a separating number of the dummy elements DMC to a total number of the dummy elements DMC), so as to improve the sintering effect, thereby improving the successful rate of the manufacturing process. Also, the laser transfer process serving as the first transfer process TP1 may be adjusted according to the result of the preset laser transfer process. For instance, if the desorption rate of the dummy elements DMC is greater than 90% or 95%, it can be determined that the sintering effect on the test adhesive layer TAF caused by the laser beam L is well. In addition, the energy density of the laser beam L and/or the irradiating time of the laser beam L may be adjusted according to the comparison between a predetermined desorption rate and the desorption rate of the dummy elements DMC measured in the second test TT2. For instance, when the desorption rate of the dummy elements DMC measured in the second test TT2 is less than the predetermined desorption rate, the energy density and/or the irradiating time of the laser beam L may be adjusted higher, but not limited thereto.

Moreover, in the first test TT1 and the second test TT2 shown in FIG. 11, the test substrate TSB may be directly replaced with the first substrate 110 also (i.e., the test adhesive layer TAF shown in FIG. 11 may be directly replaced with the first adhesive layer 120), and the dummy elements DMC of the second test TT2 may be disposed in a dummy region of the first substrate 110, wherein the dummy region may be located on the periphery of the first substrate 110 and surround the electronic elements EC for instance.

Furthermore, in the laser transfer process, the laser beam L may correspondingly separate one electronic element EC or a plurality of electronic elements EC based on an irradiating area of the laser beam L. Note that, the boundary of the laser beam L should irradiate on the light shielding layer LSL to prevent the laser beam L from passing through a part of one opening OP to irradiate a part of the first portion 120a of the first adhesive layer 120, thereby avoiding an undesirable sintering effect on the first portion 120a of the first adhesive layer 120 and preventing the first normal electronic element ECn1 from being unable to be separated for affecting the yield rate.

In addition, a light-adjusting component may be optionally disposed on the mask MK, wherein the light-adjusting component is configured to adjust and modify the optical path of the laser beam L. For example, the light-adjusting component may include a lens, so that the light-adjusting component may focus the laser beam L to increase the energy density of the laser beam L, but not limited thereto.

In order to increase the effect and the successful rate of the first transfer process TP1, before performing the first transfer process TP1, a cleaning process may be optionally performed to clean the first substrate 110. In some embodiments, the cleaning process may include a deionized (DI) water cleaning process, wherein the DI water cleaning process may clean the first substrate 110 through the DI water to remove the foreign matter (e.g., fragments, particles, etc.). For example, the temperature of the DI water may be greater than or equal to 40° C., such that the DI water is easy to volatilize without leaving any residue, but not limited thereto. In some embodiments, the cleaning process may include an air suction cleaning process, wherein the air suction cleaning process may suction (e.g., vacuum) to remove the foreign matter on the first substrate 110. For instance, the air suction cleaning process may be configured to clean the intervals between the electronic elements EC, but not limited thereto. In some embodiments, the cleaning process may include an air blowing cleaning process, wherein the air blowing cleaning process may blow air on the first substrate 110 to remove the foreign matter. For instance, the air blowing cleaning process may be configured to clean the electronic elements EC, but not limited thereto.

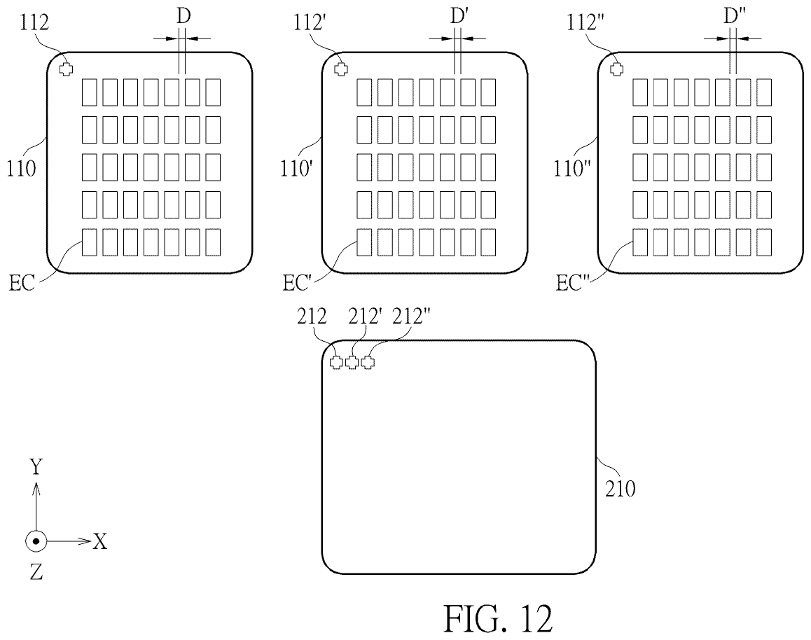

Referring to FIG. 12, FIG. 12 is a schematic diagram showing a top view of an alignment structure using in the first transfer process of a method of manufacturing an electronic device according to an embodiment of the present disclosure. As shown in FIG. 12, in the alignment process of the first transfer process TP1, the first substrate 110 and the second substrate 210 may be aligned with each other through a first alignment structure 112 on the first substrate 110 and a second alignment structure 212 on the second substrate 210, so as to make the electronic element EC be disposed at the correct location on the second substrate 210.

In some embodiments (as shown in FIG. 12), different types of electronic elements EC may be transferred to the second substrate 210. Thus, a first substrate 110 with a plurality of electronic elements EC (e.g., a blue light emitting elements) disposed thereon, a first substrate 110′ with a plurality of electronic elements EC′ (e.g., a red light emitting elements) disposed thereon and a first substrate 110″ with a plurality of electronic elements EC″ (e.g., a green light emitting elements) disposed thereon may be provided, and the first substrates 110, 110′ and 110″ respectively have the first alignment structures 112, 112′ and 112″. In the present disclosure, the sizes of the electronic elements EC, EC′ and EC″ may be the same or different based on requirement (s), and a distance D between the electronic elements EC on the first substrate 110, a distance D′ between the electronic elements EC′ on the first substrate 110′ and a distance D″ between the electronic elements EC″ on the first substrate 110″ may be the same or different based on requirement(s). For example, in FIG. 12, the sizes of the electronic elements EC, EC′ and EC″ may be the same, and the distances D, D′ and D″ may be the same.

In some embodiments (as shown in FIG. 12), the second substrate 210 may have three second alignment structures 212, 212′ and 212″ disposed at different positions. In the alignment process, the first alignment structure 112 of the first substrate 110 may be aligned with the second alignment structure 212, the first alignment structure 112′ of the first substrate 110′ may be aligned with the second alignment structure 212′, and the first alignment structure 112″ of the first substrate 110″ may be aligned with the second alignment structure 212″, such that the electronic elements EC, EC′ and EC″ may be disposed at different positions, wherein the position relation of three second alignment structures 212, 212′ and 212″ of the second substrate 210 is related to a distance between the predetermined locations on the second substrate 210 where the transferred electronic elements EC, EC′ and EC″ are disposed. For example, a distance between two adjacent second alignment structures 212 and 212′ may be the same as a distance between the predetermined location on the second substrate 210 where the transferred electronic element EC is disposed and the predetermined location on the second substrate 210 where the transferred electronic element EC′ is disposed, but not limited thereto.

In some embodiments (not shown in figures), in the alignment process, the first alignment structures 112, 112′ and 112″ of the first substrates 110, 110′ and 110″ may be aligned with the same second alignment structure 212. Then, the first substrate 110′ may move a first distance in a direction, and the first substrate 110″ may move a second distance in this direction, wherein the first distance may be the same as a distance between the predetermined locations on the second substrate 210 where the transferred electronic elements EC and EC′ are disposed respectively, and the second distance may be the same as a distance between the predetermined locations on the second substrate 210 where the transferred electronic elements EC and EC″ are disposed respectively, but not limited thereto.

In some embodiments, the first transfer process TP1 may perform multiple transfers from one first substrate 110 to the second substrate 210. For instance, the second substrate 210 may have a plurality of second alignment structures 212 related to this first substrate 110, an alignment process may be performed to align the first substrate 110 with the second substrate 210 according to one of the second alignment structures 212 during the first transfer in the first transfer process TP1, and another alignment process may be performed to align the first substrate 110 with the second substrate 210 according to another one of the second alignment structures 212 during the second transfer in the first transfer process TP1, so as to transfer the electronic elements EC to different locations on the second substrate 210. In this condition, the size of the first substrate 110 may be less than the size of the second substrate 210, but not limited thereto.

In addition, electronic elements related to sensing may also be transferred to the second substrate 210. Thus, a substrate with the sensing electronic elements disposed thereon may be provided, and the substrate may be aligned with the second substrate 210 through an alignment structure on the substrate and the second alignment structure 212 on the second substrate 210. The arrangement of the sensing electronic elements on the second substrate 210 may be designed based on requirement(s). For instance, the electronic elements configured to sense light may have a larger size and be arranged with larger intervals, and the electronic elements configured to sense fingerprints may have a smaller size and be arranged in multiple groups (i.e., multiple electronic elements may be arranged in one group, and multiple groups may be arranged with suitable intervals), but not limited thereto.

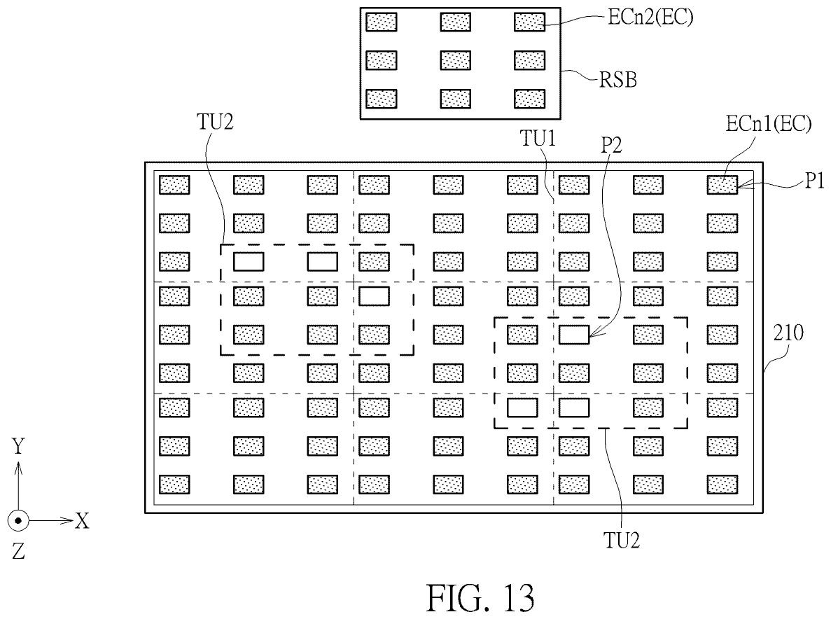

Referring to FIG. 13, FIG. 13 is a schematic diagram showing a top view of a result of a first transfer process and a configuration of a first repairing process of a method of manufacturing an electronic device according to an embodiment of the present disclosure. As shown in FIG. 13, after completing the first transfer process TP1, the first normal electronic element ECn1 is disposed on the first location P1 of the second substrate 210, and no electronic element EC is disposed on the second location P2 of the second substrate 210 (the first defective electronic element ECd1 is not transferred, such that no electronic element EC is disposed on the second location P2). For example, in the second substrate 210 shown in FIG. 13, the first transfer process TP1 transfers the first normal electronic elements ECn1 to the second substrate 210 through nine transfers, and each transfer is based on a transferring unit TU1 of a 3×3 matrix. Thus, if these nine transfers are carried out sequentially from left to right and then from top to bottom in FIG. 13, the situation that the first defective electronic elements ECd1 are not transferred occurs in the first transfer, the fifth transfer, the sixth transfer, the eighth transfer and the ninth transfer, but not limited thereto.

As shown in FIG. 1 and FIG. 13, in a step ST5 of the manufacturing method MT of the electronic device, a first abnormality analysis is performed to confirm whether a first abnormal event occurs. The first abnormality analysis may analyze the first inspecting result of the first inspecting process DP1. For instance, the first abnormal event may be that a number of the second location(s) P2 of the second substrate 210 is greater than a predetermined value, and/or the first abnormal event may be that two of the second locations P2 of the second substrate 210 are adjacent. When the first abnormality analysis determines that it is abnormal and the first abnormal event occurs, a first repairing process (i.e., a step ST6) will be performed. When the first abnormality analysis determines it is normal and the first abnormal event does not occur, the first repairing process will be omitted.

As shown in FIG. 1 and FIG. 13, in a step ST6 of the manufacturing method MT of the electronic device, a first repairing process is performed. According to the first abnormality analysis and the first inspecting result of the first inspecting process DP1, the first repairing process transfers a second normal electronic element ECn2 from a repairing substrate RSB to the second location P2 of the second substrate 210. The repairing substrate RSB may be the first substrate 110, such that the second normal electronic element ECn2 may be an electronic element EC which is normal, disposed on the first substrate 110 and not transferred (e.g., the second normal electronic element ECn2 may be other normal electronic element ECo disposed outside the preset region DR). Or, the repairing substrate RSB may be other substrate different from the first substrate 110, such that the second normal electronic element ECn2 may be an electronic element EC which is normal and disposed on other substrate.

In the present disclosure, the first repairing process may include a second transfer process. In the second transfer process, an alignment process is performed to make the second normal electronic element ECn2 be corresponding to and overlap the second location P2 of the second substrate 210 in the direction Z. Then, the second normal electronic element ECn2 is transferred from the repairing substrate RSB to the second location P2 of the second substrate 210 through any suitable manner, so as to complete the second transfer process, wherein the second normal electronic element ECn2 is adhered to the second substrate 210 through the second adhesive layer 240 disposed on the second substrate 210. Since the first normal electronic element ECn1 has been disposed on the second substrate 210, a distance between the repairing substrate RSB and the second substrate 210 in the direction Z during the second transfer process may be greater than a distance between the first substrate 110 and the second substrate 210 in the direction Z during the first transfer process TP1. For instance, the distance between the repairing substrate RSB and the second substrate 210 in the direction Z during the second transfer process may be greater than twice the height of the electronic element EC, but not limited thereto.

In some embodiments, the second transfer process may be similar to the first transfer process TP1. Thus, the second transfer process may be another laser transfer process, such that the step of transferring the second normal electronic element ECn2 is performed through another laser transfer process, wherein one transfer in the laser transfer process may transfer at least one second normal electronic element ECn2, but not limited thereto. For instance, in FIG. 13, each transfer in the second transfer process is based on a transferring unit TU2 of a 3×3 matrix. According to the first abnormality analysis and the first inspecting result of the first inspecting process DP1, the transfers of the second transfer process may be appropriately designed to reduce the number of the transfers. For example, in FIG. 13, the second transfer process transfers the second normal electronic elements ECn2 to the second substrate 210 through two transfers, and the position corresponding to the transferring unit TU2 in the second transfer process may be different from the position corresponding to the transferring unit TU1 in the first transfer process TP1.

In some embodiments, the second transfer process may be a stamp transfer process, such that the step of transferring the second normal electronic element ECn2 is performed through the stamp transfer process, wherein one of the transfers in the stamp transfer process may transfer one second normal electronic element ECn2, but not limited thereto. In some embodiments, the repairing substrate RSB may have a protruding part, and the second normal electronic element ECn2 may be disposed on the protruding part, such that the second normal electronic element ECn2 may be closer to the second substrate 210 during the second transfer process, thereby increasing the successful rate of the second transfer process. Note that, the second location P2 of the second substrate 210 may be adjacent to two first normal electronic elements ECn1 in a horizontal direction (i.e., the second location P2 may be between two first normal electronic elements ECn1 in this horizontal direction), a distance between these two first normal electronic elements ECn1 in this horizontal direction should be greater than the size of the protruding part in this horizontal direction.

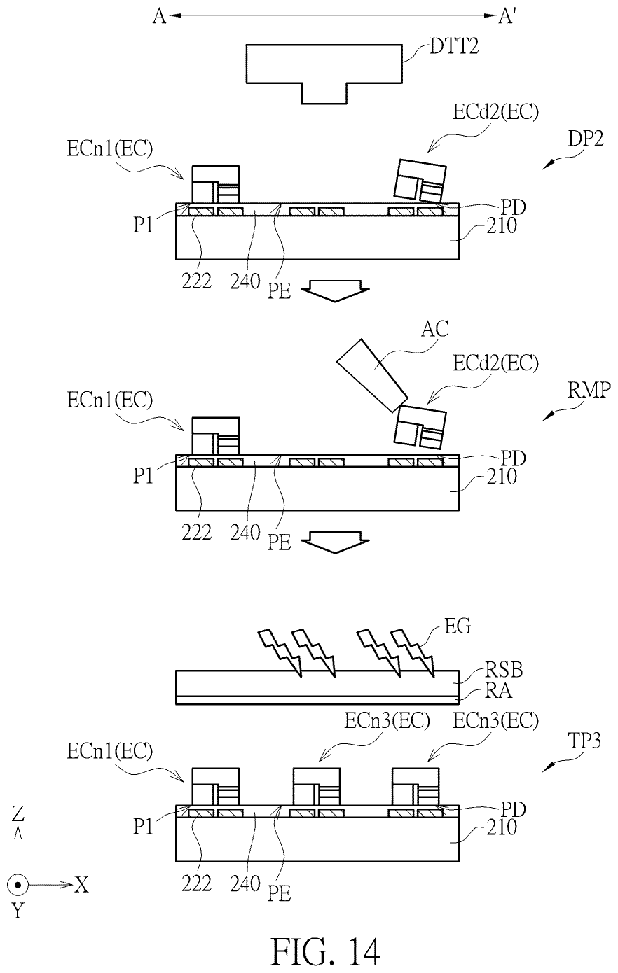

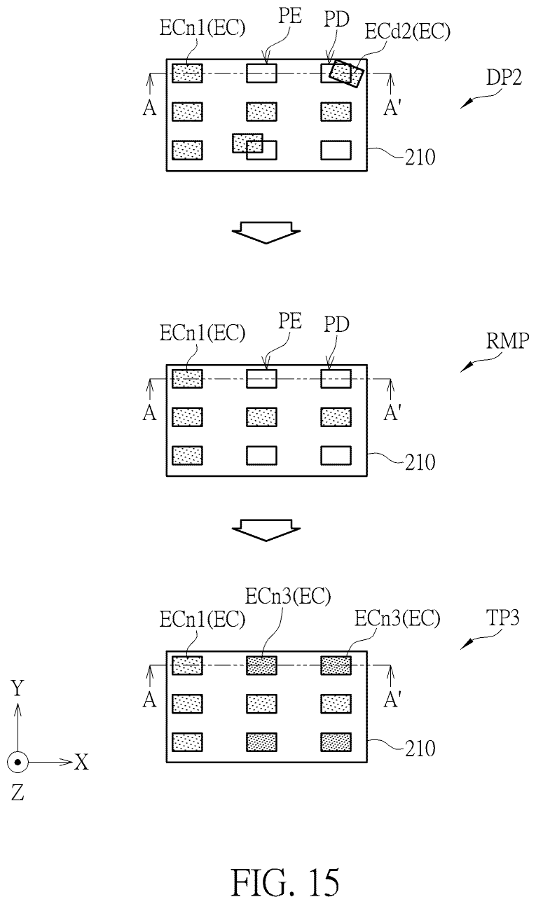

Referring to FIG. 14 and FIG. 15 with FIG. 1, FIG. 14 is a schematic diagram showing a cross-sectional view of a second inspecting process and a second repairing process of a method of manufacturing an electronic device according to an embodiment of the present disclosure, and FIG. 15 is a schematic diagram showing a top view of the second inspecting process and the second repairing process of the method of manufacturing the electronic device according to the embodiment shown in FIG. 14, wherein the cross-sectional structure shown in FIG. 14 is corresponding to the cross-sectional line AA′ in FIG. 15. As shown in FIG. 1, FIG. 14 and FIG. 15, in a step ST7 of the manufacturing method MT of the electronic device, a second inspecting process DP2 is performed. In the second inspecting process DP2, the second substrate 210 and the electronic elements EC on the second substrate 210 (i.e., the first normal electronic elements ECn1 transferred by the first transfer process TP1 and the second normal electronic elements ECn2 transferred by the second transfer process) may be inspected by a detector DTT2, thereby confirming the transfer results of the first transfer process TP1 and the second transfer process and correspondingly generating a second inspecting result (e.g., a chart). In some embodiments, the second inspecting process DP2 may include a visual inspection, a lighting inspection, other suitable inspection or a combination thereof, and the detector DTT2 may be correspondingly adjusted according to the inspection(s) of the second inspecting process DP2.

In some embodiments, the second inspecting process DP2 may be used to confirm whether an empty location PE where the electronic element EC is not disposed exists on the second substrate 210, and may identify the empty location PE, wherein the empty location PE may be caused by one reason or a plurality of reasons. For instance, the empty location PE may be the second location P2 where the first repairing process is not performed, but not limited thereto. For instance, after transferring the first normal electronic element ECn1 and/or the second normal electronic element ECn2 to the second substrate 210, the first normal electronic element ECn1 and/or the second normal electronic element ECn2 may be separated from the second substrate 210 due to at least one reason (e.g., they may not be firmly adhered), and the first normal electronic element ECn1 and/or the second normal electronic element ECn2 separated from the second substrate 210 may be removed to generate the empty location PE, but not limited thereto.

In some embodiments, the second inspecting process DP2 may be used to confirm whether the electronic elements EC on the second substrate 210 (i.e., the first normal electronic elements ECn1 transferred by the first transfer process TP1 and the second normal electronic elements ECn2 transferred by the second transfer process) are placed at their correct locations. Also, in the second inspecting process DP2, the electronic element EC that is not placed in its correct location is identified and referred as a second defective electronic element ECd2. For instance, the second defective electronic element ECd2 has an offset (or a deflection) in a horizontal direction and/or a skew in the direction Z relative to its correct location, but not limited thereto. Note that the location of the second substrate 210 corresponding to the second defective electronic element ECd2 may be referred as a defective location PD. Furthermore, similar to the first inspecting process DP1, the second inspecting process DP2 may also inspect the electronic element EC on the second substrate 210 to confirm whether the electronic element EC is damaged, wherein the damaged electronic element EC is identified and referred as a second defective electronic element ECd2.

For example, the second inspecting process DP2 in FIG. 15 shows two second defective electronic elements ECd2 (two defective locations PD) and two empty locations PE, such that FIG. 14 corresponding to the cross-sectional line AA′ of FIG. 15 shows one second defective electronic element ECd2 (one defective location PD) and one empty location PE.

As shown in FIG. 1, FIG. 14 and FIG. 15, in a step ST8 of the manufacturing method MT of the electronic device, a second abnormality analysis is performed whether a second abnormal event occurs. The second abnormality analysis may analyze the second inspecting result of the second inspecting process DP2. For instance, the second abnormal event may be that a sum of a number of the empty location(s) PE of the second substrate 210 and a number of the second defective electronic element(s) ECd2 on the second substrate 210 is greater than a predetermined value (e.g., a ratio of a sum of the number of the empty location(s) PE and the number of the second defective electronic element(s) ECd2 to a design number of the electronic elements EC of the electronic device is greater than 1/100000), and/or the second abnormal event may be that two of the empty locations PE are adjacent, two of the second defective electronic elements ECd2 are adjacent or one of the empty locations PE and one of the second defective electronic elements ECd2 are adjacent. When the second abnormality analysis determines that it is abnormal and the second abnormal event occurs, a second repairing process (i.e., a step ST9) will be performed. When the second abnormality analysis determines that it is normal and the second abnormal event does not occur, the second repairing process will be omitted.

As shown in FIG. 1, FIG. 14 and FIG. 15, in a step ST9 of the manufacturing method MT of the electronic device, a second repairing process is performed. According to the second abnormality analysis and the second inspecting result of the second inspecting process DP2, the second repairing process repairs the empty location(s) PE and the second defective electronic element(s) ECd2 on the second substrate 210, so as to decrease the number of the empty location(s) PE and the number of the second defective electronic element (s) ECd2.

As shown in FIG. 14 and FIG. 15, the second repairing process may include a removing process RMP configured to remove the second defective electronic element ECd2. For example, in FIG. 14, the second defective electronic element ECd2 is removed from the second substrate 210 by a sucking component AC (or an adhering component), but not limited thereto. Since the second defective electronic element ECd2 is removed through the removing process RMP, the defective location PD of the second substrate 210 corresponding to the second defective electronic element ECd2 becomes empty.

As shown in FIG. 14 and FIG. 15, the second repairing process may include a third transfer process TP3, so as to transfer a third normal electronic element ECn3 from a repairing substrate RSB to the empty location PE or the empty defective location PD of the second substrate 210. The repairing substrate RSB may be the first substrate 110, such that the third normal electronic element ECn3 may be an electronic element EC which is normal, disposed on the first substrate 110 and not transferred (e.g., the third normal electronic element ECn3 may be other normal electronic element ECo disposed outside the preset region DR). Or, the repairing substrate RSB may be other substrate different from the first substrate 110, such that the third normal electronic element ECn3 may be an electronic element EC which is normal and disposed on other substrate. The third normal electronic element ECn3 may be adhered to the repairing substrate RSB through an adhesive layer RA.

In the third transfer process TP3, an alignment process is performed to make the third normal electronic element ECn3 be corresponding to and overlap the empty location PE or the empty defective location PD of the second substrate 210 in the direction Z. Then, the third normal electronic element ECn3 is transferred from the repairing substrate RSB to the empty location PE or the empty defective location PD of the second substrate 210 through any suitable manner, so as to complete the third transfer process TP3, wherein the third normal electronic element ECn3 is adhered to the second substrate 210 through the second adhesive layer 240 disposed on the second substrate 210 after being transferred. Since the first normal electronic element ECn1 and the second normal electronic element ECn2 have been disposed on the second substrate 210, a distance between the repairing substrate RSB and the second substrate 210 in the direction Z during the third transfer process TP3 may be greater than a distance between the first substrate 110 and the second substrate 210 in the direction Z during the first transfer process TP1. For instance, the distance between the repairing substrate RSB and the second substrate 210 in the direction Z during the third transfer process TP3 may be greater than twice the height of the electronic element EC, but not limited thereto. In some embodiments, since the empty location PE may be the second location P2 where the first repairing process (the second transfer process) is not performed, the empty location PE may also be regarded as the second location P2, such that a single laser transfer process may transfer the third normal electronic elements ECn3 to the second location P2 and the empty location PE respectively, wherein the third normal electronic element ECn3 transferred to the second location P2 may be regarded as the aforementioned second normal electronic element ECn2.

In some embodiments, the third transfer process TP3 may be similar to the second transfer process. Therefore, the third transfer process TP3 may be still another laser transfer process or a stamp transfer process, but not limited thereto. The detail of the third transfer process TP3 can be referred to the second transfer process, and these contents will not be redundantly described.

In some embodiments, the manufacturing method MT of the electronic device may omit the first abnormality analysis in the step ST5 and the first repairing process in the step ST6, and the manufacturing method MT may respectively transfer the third normal electronic elements ECn3 to the second location P2, the empty location PE and the empty defective location PD through the second repairing process, wherein the third normal electronic element ECn3 transferred to the second location P2 may be regarded as the aforementioned second normal electronic element ECn2.

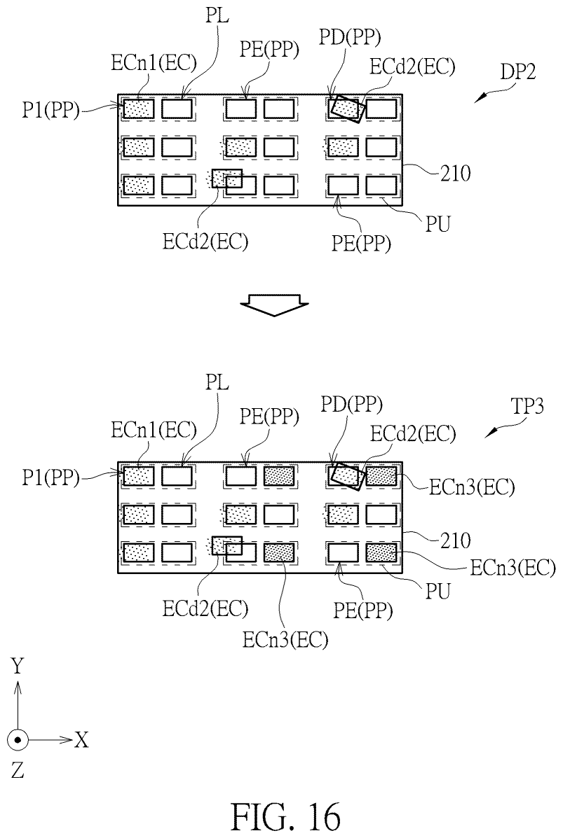

Referring to FIG. 16, FIG. 16 is a schematic diagram showing a top view of a second repairing process of a method of manufacturing an electronic device according to another embodiment of the present disclosure. In the second repairing process of another embodiment shown in FIG. 16, the second repairing process may include the third transfer process TP3 and not include the removing process. In FIG. 16, the second substrate 210 may further include a redundant location PL adjacent to a location PP where the electronic element EC is expected to be disposed (i.e., the location PP may be the first location P1, the second location P2, the empty location PE or the defective location PD). For example (as shown in FIG. 16), the electronic device may have a plurality of units PU, each unit PU include one location PP where the electronic element EC is expected to be disposed and one redundant location PL, but not limited thereto. In the condition that the second inspecting process DP2 identifies the empty location PE and/or the second defective electronic element ECd2 on the defective location PD, the third transfer process TP3 may transfer the third normal electronic element ECn3 to the redundant location PL adjacent to the empty location PE or the redundant location PL adjacent to the defective location PD, so as to achieve the repairing effect.

After completing the second repairing process, the manufacturing method MT may return to the step ST7 and perform the second inspecting process DP2 again, and the manufacturing method MT may confirm whether the second abnormal event occurs through the second abnormality analysis in the step ST8.

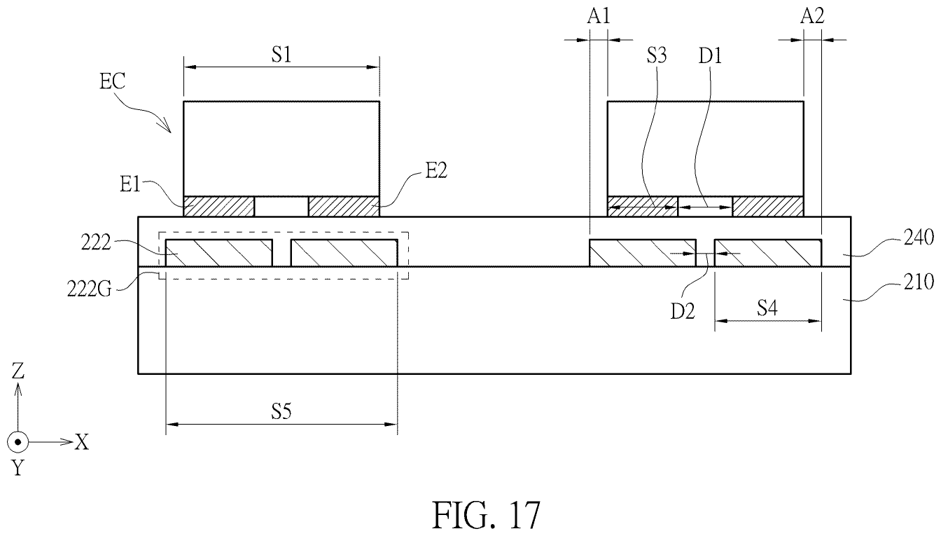

In the present disclosure, after performing the second inspecting process DP2 and the second repairing process, the dispositions of the first normal electronic element ECn1, the second normal electronic element ECn2 and the third normal electronic element ECn3 on the second substrate 210 may be referred to FIG. 17.

In FIG. 17, the first normal electronic element ECn1, the second normal electronic element ECn2 and the third normal electronic element ECn3 are corresponding to connecting pads 222 in the direction Z. For instance, in FIG. 17, each electronic element EC may be corresponding to two connecting pads 222 (in the following, a connecting pad group 222G includes the connecting pads 222 corresponding to the same electronic element EC), such that the electrode E1 may be corresponding to one connecting pad 222 in the direction Z only, and the electrode E2 may be corresponding to another connecting pad 222 in the direction Z only. In some embodiments, the size S4 of the connecting pad 222 in a horizontal direction (e.g., the direction X) may be greater than or equal to the sizes S3 of the electrodes E1 and E2 in this horizontal direction, such that a distance S5 between two opposite edges of the connecting pad group 222G in this horizontal direction may be greater than or equal to the size S1 of the electronic element EC in this horizontal direction, so as to enhance the successful rate of bonding the electronic element EC and the connecting pads 222 in the subsequent step. Similarly, in the top view, an area surrounded by the edges of the connecting pad group 222G may be greater than an area of the electronic element EC, so as to enhance the successful rate of bonding the electronic element EC and the connecting pads 222 in the subsequent step.

For instance, in the top view, two opposite edges of the connecting pad group 222G may be situated on the outer side of the electronic element EC, so as to enhance the successful rate of bonding the electronic element EC and the connecting pads 222 in the subsequent step. In FIG. 17, in order to make two opposite edges of the connecting pad group 222G situated on the outer side of the electronic element EC, in a horizontal direction (e.g., the direction X), a difference between a sum of a size S1 of the electronic element EC, a distance A1 between the electronic element EC and one edge of the connecting pad group 222G and a distance A2 between the electronic element EC and another edge of the connecting pad group 222G and a distance S5 between two opposite edges of the connecting pad group 222G is greater than or equal to 0 and less than a sum of a distance D1 between two electrodes E1 and E2 of the electronic element EC and a distance D2 between two connecting pads 222 of the connecting pad group 222G (i.e., 0≤(S1+A1+A2−S5)<(D1+D2)), but not limited thereto.

Moreover, in order to prevent the electrode E1 or the electrode E2 from being stuck in the gap between two connecting pads 222 of the connecting pad group 222G, the sizes S3 of the electrodes E1 and E2 in the horizontal direction (e.g., the direction X) are greater than the distance D2 between two connecting pads 222 of the connecting pad group 222G in this horizontal direction, but not limited thereto.

As shown in FIG. 1 and FIG. 17, a step ST10 in the manufacturing method MT of the electronic device, a bonding process is performed to bond the electronic elements EC on the corresponding locations of the second substrate 210 (i.e., the first normal electronic element ECn1 is bonded on the first location P1, the second normal electronic element ECn2 is bonded on the second location P2, and the third normal electronic element ECn3 is bonded on the empty location PE or the empty defective location PD). For example, the bonding process may bond the electronic elements EC on the corresponding locations of the second substrate 210 through a heating manner, a pressuring manner, a light-illuminating manner or a combination thereof. For instance, in an example of the bonding process, the second substrate 210 may be heated, and a thermally pressing process is performed on the electronic element EC and the second substrate 210 through appropriate tool(s), so as to bond the electronic element EC on the connection pads 222, but not limited thereto. For instance, the tool for performing the thermally pressing process may be a plate-like structure or a stick structure, but not limited thereto.

As shown in FIG. 1 and FIG. 2, after performing the bonding process of the step ST10, in a step ST11 of the manufacturing method MT of the electronic device, a third inspecting process is performed. In the third inspecting process, the second substrate 210 and the electronic elements EC on the second substrate 210 may be inspected by a detector, thereby confirming the bonding results of the bonding process and correspondingly generating a third inspecting result (e.g., a chart). In some embodiments, the third inspecting process may include a visual inspection, a lighting inspection, an electrical inspection, other suitable inspection or a combination thereof, and the detector may be correspondingly adjusted according to the inspection(s) of the third inspecting process.

In some embodiments, the third inspecting process may be used to confirm whether an empty location where the electronic element EC is not disposed exists on the second substrate 210, and may identify the empty location, wherein the empty location may be caused by one reason or a plurality of reasons. For instance, the empty location may be the second location P2 where the first repairing process and the second repairing process are not performed, but not limited thereto. For instance, the first normal electronic element ECn1, the second normal electronic element ECn2 and/or the third normal electronic element ECn3 may be separated from the second substrate 210 and not be bonded on the second substrate 210 due to at least one reason (e.g., defects caused by the bonding process), thereby generating the empty location, but not limited thereto.

In some embodiments, the third inspecting process may be used to confirm whether the electronic element EC on the second substrate 210 is properly bonded on the connecting pads 222, and the electronic element EC that is not properly bonded on the connecting pads 222 is identified and referred as a third defective electronic element. For example, a bonding problem occurs on the third defective electronic element and its corresponding connecting pads 222 to make the third defective electronic element be not able to be performed a normally electrical operation, but not limited thereto. Note that the location of the second substrate 210 corresponding to the third defective electronic element may be referred as a defective location. Furthermore, similar to the first inspecting process DP1 and the second inspecting process DP2, the third inspecting process may also inspect the electronic element EC on the second substrate 210 to confirm whether the electronic element EC is damaged, wherein the damaged electronic element EC is identified and referred as a third defective electronic element.

As shown in FIG. 2, in a step ST12 of the manufacturing method MT of the electronic device, a third abnormality analysis is performed to confirm whether a third abnormal event occurs. The third abnormality analysis may analyze the third inspecting result of the third inspecting process. For example, the third abnormal event may be that a sum of a number of the empty location(s) of the second substrate 210 and a number of the third defective electronic element(s) on the second substrate 210 is greater than a predetermined value (e.g., a ratio of a sum of the number of the empty location(s) and the number of the third defective electronic element(s) to a design number of the electronic elements EC of the electronic device is greater than 1/10000). When the third abnormality analysis determines that it is abnormal and the third abnormal event occurs, a third repairing process (i.e., a step ST13) will be performed. When the third abnormality analysis determines that it is normal and the third abnormal event does not occur, the third repairing process will be omitted.

As shown in FIG. 2, in a step ST13 of the manufacturing method MT of the electronic device, a third repairing process is performed. According to the third abnormality analysis and the third inspecting result of the third inspecting process, the third repairing process repairs the empty location(s) of the second substrate 210 and the third defective electronic element(s) on the second substrate 210, so as to decrease the number of the empty location(s) and the number of the third defective electronic element(s).

When the third repairing process needs to repair the empty location(s), a step ST13_1 may be performed to bond a fourth normal electronic element on the empty location. In detail, the fourth normal electronic element is transferred from a repairing substrate to the empty location of the second substrate 210, and the fourth normal electronic element is bonded on the connecting pads 222, thereby filling the empty location. The repairing substrate may be the first substrate 110, such that the fourth normal electronic element may be an electronic element EC which is normal, disposed on the first substrate 110 and not transferred (e.g., the fourth normal electronic element may be other normal electronic element ECo disposed outside the preset region DR). Or, the repairing substrate may be other substrate different from the first substrate 110, such that the fourth normal electronic element may be an electronic element EC which is normal and disposed on other substrate.

In some embodiments, when the third repairing process needs to repair the third defective electronic element, a step ST13_2 may be performed to perform a removing process to remove the third defective electronic element. In detail, the removing process of the step ST13_2 may release the bond between the third defective electronic element and the connecting pads 222, and next, the third defective electronic element may be removed from the second substrate 210 by a sucking component (or an adhering component), such that the defective location of the second substrate 210 corresponding to this third defective electronic element may become empty. Then, a step ST13_3 may be optionally performed to bond the fourth normal electronic element on this empty defective location. In detail, the fourth normal electronic element may be transferred to this empty defective location of the second substrate 210, and then, the fourth normal electronic element may be bonded on the connecting pads 222, thereby filling this empty defective location.

In some embodiments, when the third repairing process needs to repair the third defective electronic element, a step ST13_4 may be performed to perform an electrically isolating process to electrically isolate the third defective electronic element from the second substrate 210 (e.g., the third defective electronic element may be electrically isolated from a driving component on the second substrate 210). For instance, the electrically isolating process may be achieved by cutting off a conductive line electrically connected to the third defective electronic element, but not limited thereto. Optionally, a step ST13_5 may be performed to bond the fourth normal electronic element on a redundant location PL adjacent to the third defective electronic element. In detail, the fourth normal electronic element may be transferred to the redundant location PL of the second substrate 210, and then, the fourth normal electronic element may be bonded on the connecting pads 222 of the redundant location PL.

Note that the step of transferring the fourth normal electronic element in the steps ST13_1, ST13_3 and ST13_5 may be performed through the same transfer process or different transfer processes. Since the first normal electronic element ECn1, the second normal electronic element ECn2 and the third normal electronic element ECn3 have been disposed on the second substrate 210, a distance between two substrates during the transfer process(es) in the steps ST13_1, ST13_3 and ST13_5 may be greater than a distance between the first substrate 110 and the second substrate 210 during the first transfer process TP1. The transfer process (es) in the steps ST13_1, ST13_3 and ST13_5 may be similar to the third transfer process TP3, and thus, the transfer process (es) may be the laser transfer process(es) or the stamp transfer process(es), but not limited thereto. The detail of the transfer process(es) can be referred to the third transfer process TP3, and these contents will not be redundantly described.

After completing the third repairing process, the manufacturing method MT may return to the step ST11 and perform the third inspecting process again, and the manufacturing method MT may confirm whether the third abnormal event occurs through the third abnormality analysis in the step ST12.

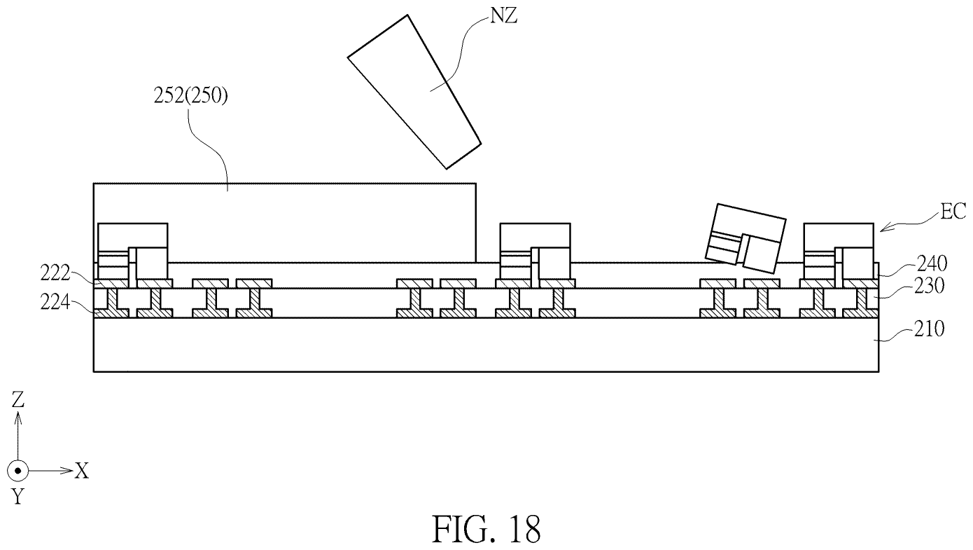

Referring to FIG. 18 with FIG. 2, FIG. 18 is a schematic diagram showing a cross-sectional view of a forming process of a filling layer of a method of manufacturing an electronic device according to an embodiment of the present disclosure. As shown in FIG. 2 and FIG. 18, in a step ST14 of the manufacturing method MT of the electronic device, a forming process of a filling layer 250 is performed, such that the filling layer 250 is formed on the second substrate 210 and covers the electronic elements EC, so as to protect the electronic elements EC. For example, in FIG. 18, a filling material 252 is applied on the second substrate 210 through a nozzle NZ, so as to form the filling layer 250. A portion of the filling material 252 may be disposed on the electronic elements EC (the first normal electronic element ECn1, the second normal electronic element ECn2, the third normal electronic element ECn3 and the fourth normal electronic element), and another portion of the filling material 252 may be between the second substrate 210 and the electronic elements EC (the first normal electronic element ECn1, the second normal electronic element ECn2, the third normal electronic element ECn3 and the fourth normal electronic element). In some embodiments, the filling material 252 may include an insulating material, such that the filling layer 250 may be an insulating layer.

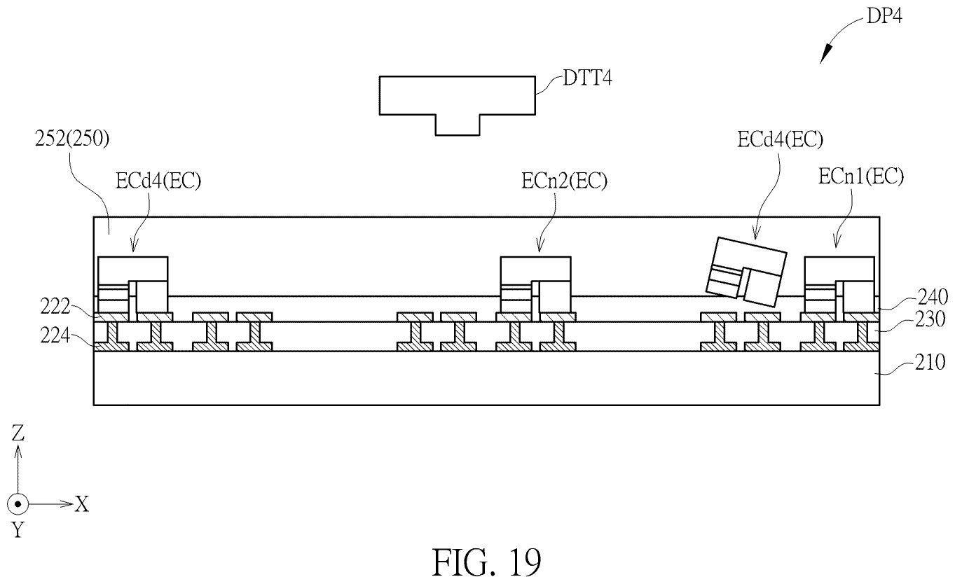

Referring to FIG. 19 with FIG. 2, FIG. 19 is a schematic diagram showing a cross-sectional view of a fourth inspecting process of a method of manufacturing an electronic device according to an embodiment of the present disclosure. As shown in FIG. 2 and FIG. 19, after completing the forming process of the filling layer 250 in the step ST14, in a step ST15 of the manufacturing method MT of the electronic device, a fourth inspecting process DP4 is performed. In the fourth inspecting process DP4, the second substrate 210 and the electronic elements EC on the second substrate 210 may be inspected by a detector DTT4 after forming the filling layer 250, thereby correspondingly generating a fourth inspecting result (e.g., a chart). In some embodiments, the fourth inspecting process DP4 may include a visual inspection, a lighting inspection, an electrical inspection, other suitable inspection or a combination thereof, and the detector DTT4 may be correspondingly adjusted according to the inspection(s) of the fourth inspecting process DP4.

In some embodiments, the fourth inspecting process DP4 may be used to confirm whether the electronic element EC on the second substrate 210 is able to be performed a normally electrical operation, and the electronic element EC that is not able to be performed the normally electrical operation (e.g., this electronic element EC constantly lights or has other abnormal event) is identified and referred as a fourth defective electronic element ECd4. For instance, in FIG. 19, the fourth defective electronic element ECd4 on the left side may be in a constant light state, and the fourth defective electronic element ECd4 on the right side may have an abnormal event. Furthermore, similar to the first inspecting process DP1, the second inspecting process DP2 and the third inspecting process, the fourth inspecting process DP4 may also inspect the electronic element EC on the second substrate 210 to confirm whether the electronic element EC is damaged, wherein the damaged electronic element EC is identified and referred as a fourth defective electronic element ECd4.

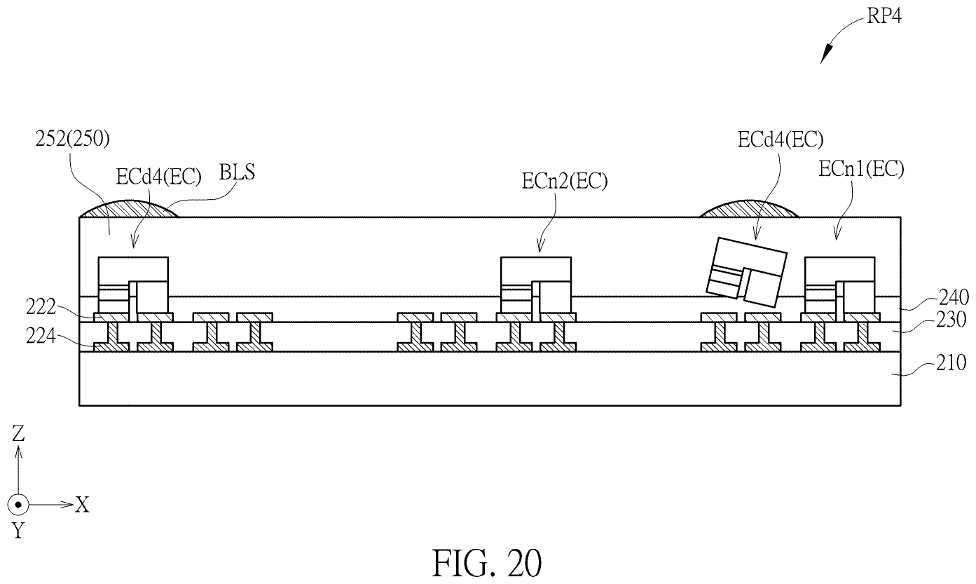

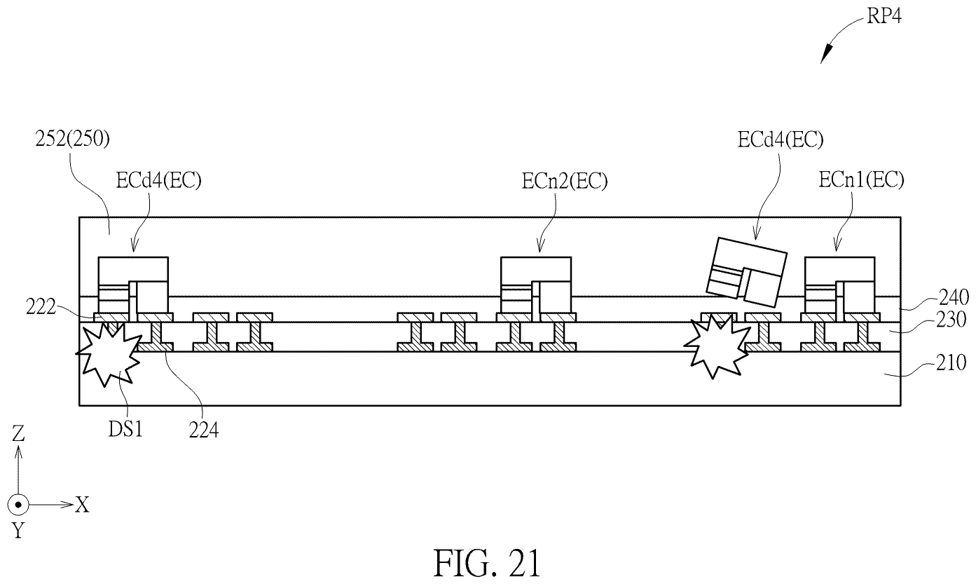

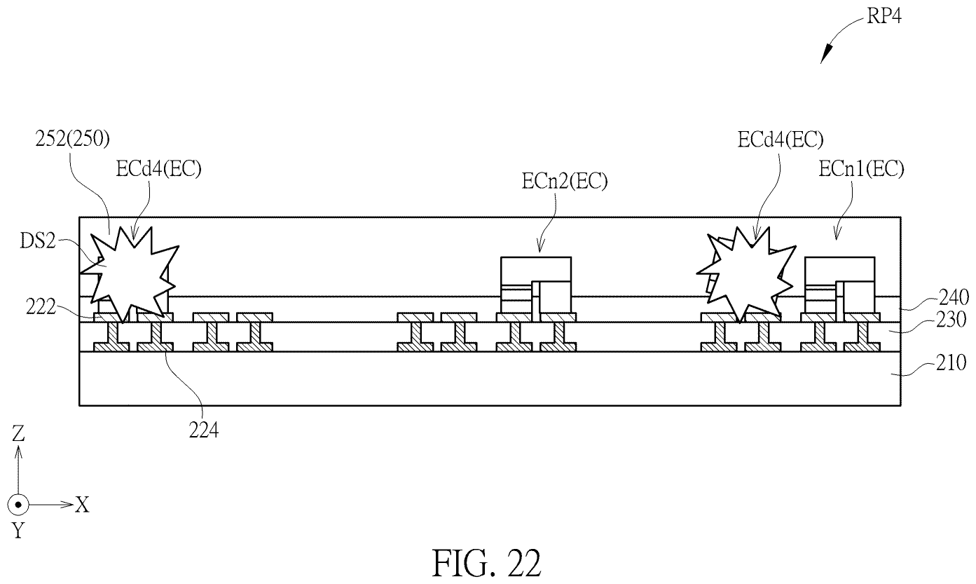

Referring to FIG. 20 to FIG. 22 with FIG. 2, FIG. 20 is a schematic diagram showing a cross-sectional view of a fourth repairing process of a method of manufacturing an electronic device according to an embodiment of the present disclosure, FIG. 21 is a schematic diagram showing a cross-sectional view of a fourth repairing process of a method of manufacturing an electronic device according to another embodiment of the present disclosure, and FIG. 22 is a schematic diagram showing a cross-sectional view of a fourth repairing process of a method of manufacturing an electronic device according to still another embodiment of the present disclosure. As shown in FIG. 2, in a step ST16 of the manufacturing method MT of the electronic device, a fourth repairing process RP4 is performed. According to the fourth inspecting result of the fourth inspecting process DP4, the fourth repairing process RP4 repairs the fourth defective electronic element ECd4 on the second substrate 210.

In some embodiments (as shown in FIG. 20), the fourth repairing process RP4 may apply a black material BLS on the fourth defective electronic element ECd4 to cover the fourth defective electronic element ECd4. For instance, the black material BLS may include metal, photoresist, ink, resin, pigment, other suitable material or a combination thereof, but not limited thereto.

In some embodiments (as shown in FIG. 21), the fourth repairing process RP4 may electrically isolate the fourth defective electronic element ECd4 from the second substrate 210 (e.g., the fourth defective electronic element ECd4 may be electrically isolated from a driving component on the second substrate 210). For example, in FIG. 21, the fourth repairing process RP4 may produce a damage structure DS1 on the conductive line 224 (e.g., the conductive line 224 may be cut off or blown up) electrically connected to the fourth defective electronic element ECd4, so as to electrically isolate the fourth defective electronic element ECd4 from the second substrate 210. For instance, the conductive line 224 electrically connected to the fourth defective electronic element ECd4 may be blown up through a laser beam, thereby forming the damaged structure DS1, but not limited thereto.

In some embodiments (as shown in FIG. 22), the fourth repairing process RP4 may damage the fourth defective electronic element ECd4. For instance, the fourth defective electronic element ECd4 may be blown up through a laser beam, thereby forming a damage structure DS2, but not limited thereto.

In summary, in the manufacturing method of the electronic device of the present disclosure, since the first defective electronic element can be identified through the inspecting process and the first defective electronic element is not transferred, the difficulty of the subsequent repairing process is reduced, and the yield rate of the electronic device is improved. Furthermore, since multiple inspecting processes and multiple repairing processes exist in the manufacturing method of the electronic device of the present disclosure, the impact of the processing errors between different processes would be reduced, thereby reducing the difficulty of the repairing process and improving the yield rate of the electronic device.

Although the embodiments and their advantages of the present disclosure have been described as above, it should be understood that any person having ordinary skill in the art can make changes, substitutions, and modifications without departing from the spirit and scope of the present disclosure. In addition, the protecting scope of the present disclosure is not limited to the processes, machines, manufactures, material compositions, devices, methods and steps in the specific embodiments described in the description. Any person having ordinary skill in the art can understand the current or future developed processes, machines, manufactures, material compositions, devices, methods and steps from the content of the present disclosure, and then, they can be used according to the present disclosure as long as the same functions can be implemented or the same results can be achieved in the embodiments described herein. Thus, the protecting scope of the present disclosure includes the above processes, machines, manufactures, material compositions, devices, methods and steps. Moreover, each claim constitutes an individual embodiment, and the protecting scope of the present disclosure also includes the combination of each claim and each embodiment. The protecting scope of the present disclosure shall be determined by the appended claims.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A method of manufacturing an electronic device, comprising following steps:
providing a first substrate with a plurality of electronic elements disposed thereon;
inspecting at least part of the plurality of electronic elements on the first substrate to identify a first defective electronic element and a first normal electronic element;
selectively transferring the first normal electronic element from the first substrate to a first location of a second substrate; and
transferring a second normal electronic element to a second location of the second substrate corresponding to a location of the first defective electronic element on the first substrate.

2. The method according to claim 1, wherein the step of selectively transferring the first normal electronic element is carried out by a laser transfer process.

3. The method according to claim 2, wherein the laser transfer process comprises:
directing a laser beam on the first substrate to make the first normal electronic element separate from the first substrate.

4. The method according to claim 2, wherein the laser transfer process comprises:
providing a mask having a transmissive region corresponding to the first normal electronic element and a non-transmissive region corresponding to the first defective electronic element; and
directing a laser beam on the first substrate through the transmissive region to make the first normal electronic element separate from the first substrate.

5. The method according to claim 4, wherein a number of the first normal electronic element separated from the first substrate is greater than 1.

6. The method according to claim 2, before the step of selectively transferring the first normal electronic element, the method comprising:
providing a test substrate with a plurality of dummy elements disposed thereon;
transferring the dummy elements from the test substrate to a third substrate by a preset laser transfer process; and
adjusting the laser transfer process according to a result of the preset laser transfer process.

7. The method according to claim 1, wherein the step of selectively transferring the first normal electronic element comprises:
providing a mask;
determining a transfer region on the second substrate;
determining a preset region on the mask according to the transfer region, the mask having a transmissive region within the preset region and corresponding to the first normal electronic element and a non-transmissive region out of the preset region and corresponding to a third normal electronic element;
aligning the mask with the first substrate; and
directing a laser beam on the first substrate through the transmissive region to make the first normal electronic element separate from the first substrate.

8. The method according to claim 1, wherein the step of transferring the second normal electronic element is carried out by another laser transfer process.

9. The method according to claim 1, wherein the step of transferring the second normal electronic element is carried out by a stamp transfer process.

10. The method according to claim 1, further comprising following steps:
inspecting the second substrate to identify an empty location; and
transferring a fourth normal electronic element to the empty location.

11. The method according to claim 10, wherein the step of transferring the second normal electronic element to the second location and the step of transferring the fourth normal electronic element to the empty location are carried out by a single laser transfer process.

12. The method according to claim 1, further comprising following steps:
inspecting the second substrate to identify a second defective electronic element;
removing the second defective electronic element; and
transferring a fourth normal electronic element to a defective location corresponding to the second defective electronic element.

13. The method according to claim 1, further comprising following steps:
inspecting the second substrate to identify a second defective electronic element; and
transferring a fourth normal electronic element to a redundant location adjacent to a defective location corresponding to the second defective electronic element.

14. The method according to claim 1, further comprising following steps:
bonding the first normal electronic element on the first location of the second substrate and the second normal electronic element on the second location of the second substrate.

15. The method according to claim 14, after the step of bonding the first normal electronic element and the second normal electronic element, the method comprising:
inspecting the second substrate to identify an empty location; and
transferring a fifth normal electronic element to the empty location.

16. The method according to claim 14, after the step of bonding the first normal electronic element and the second normal electronic element, the method comprising:
inspecting the second substrate to identify a third defective electronic element;
removing the third defective electronic element; and
transferring a fifth normal electronic element to a defective location corresponding to the third defective electronic element.

17. The method according to claim 14, further comprising following steps:
applying a filling material on the second substrate such that the filling material is disposed between the second substrate and the first normal electronic element and disposed between the second substrate and the second normal electronic element.

18. The method according to claim 17, after the step of applying the filling material on the second substrate, the method comprising:
inspecting the second substrate to identify a fourth defective electronic element; and
applying a black material on the fourth defective electronic element.

19. The method according to claim 17, after the step of applying the filling material on the second substrate, the method comprising:
inspecting the second substrate to identify a fourth defective electronic element; and
electrically isolating the fourth defective electronic element from the second substrate.
